(19) United States
(12) Patent Application Publication
(10) Pub. No.: US 2026/0045915 A1
(43) Pub. Date: Feb. 12, 2026

(54) AMPLIFIER CIRCUIT

(71) Applicant: Murata Manufacturing Co., Ltd., Nagaokakyo-shi (JP)

(72) Inventor: Isao TAKENAKA, Nagaokakyo-shi (JP)

(73) Assignee: Murata Manufacturing Co., Ltd., Nagaokakyo-shi (JP)

(21) Appl. No.: 19/363,688

(22) Filed: Oct. 21, 2025

Related U.S. Application Data
(63) Continuation of application No. PCT/JP2024/009020, filed on Mar. 8, 2024.

(30) Foreign Application Priority Data
Jun. 2, 2023 (JP) 2023-091937

(51) Int. Cl. H03F 1/02; H03F 3/21; H03F 3/213

(52) U.S. Cl. CPC H03F 1/0288; H03F 3/211; H03F 3/213; H03F 2200/06; H03F 2200/102; H03F 2200/451; H03F 2200/534; H03F 2203/21145

(57) ABSTRACT

An amplifier circuit includes first and second amplifiers, first and second input-side coils, first and second output-side coils, a resistance element, a first switch including first to fourth terminals, and a second switch including fifth to seventh terminals. The first input-side coil is connected between the first amplifier and the first terminal, the second input-side coil is connected between the second amplifier and the third terminal, the first output-side coil is connected between a signal output terminal and the second terminal, the second output-side coil is connected between the fifth terminal and the fourth terminal, and the resistance element is connected between the sixth terminal and the ground.

### CROSS-REFERENCE TO RELATED APPLICATIONS

The present application is a bypass continuation of International Application No. PCT/JP2024/009020, filed Mar. 8, 2024, which claims priority to Japanese patent application 2023-091937, filed Jun. 2, 2023, the entire contents of each of which being incorporated herein by reference.

### TECHNICAL FIELD

The present disclosure relates to an amplifier circuit.

### BACKGROUND ART

Patent Document 1 discloses a differential amplifier circuit in which the phase difference between output signals of two amplifiers is 180°. Also, Patent Document 2 discloses a balanced amplifier circuit in which the phase difference between output signals of two amplifiers is 90°. Furthermore, Patent Document 3 discloses a Doherty amplifier circuit in which the phase difference between output signals of a carrier amplifier and a peak amplifier is 90°.

### CITATION LIST

### Patent Documents

Patent Document 1: Japanese Unexamined Patent Application Publication No. 2021-197586
Patent Document 2: Japanese Unexamined Patent Application Publication No. 2012-147352
Patent Document 3: Japanese Unexamined Patent Application Publication No. 2018-085635

### SUMMARY

### Technical Problems

However, 4th generation (4G) and 5th generation (5G) mobile communication systems require a compact amplifier circuit that can operate in at least two of a differential amplification mode, a balanced amplification mode, and a Doherty amplification mode depending on, for example, power supply voltage supply modes, load variation, and power modes.

The present disclosure has been made to solve the above-described and other problems, and is directed to providing a compact amplifier circuit that can operate in at least two of a differential amplification mode, a balanced amplification mode, and a Doherty amplification mode. Solutions to Problems

An amplifier circuit according to an aspect of the present disclosure includes a first amplifier; a second amplifier; a combiner circuit configured to combine an output of the first amplifier and an output of the second amplifier; and a signal output terminal connected to the combiner circuit. The combiner circuit includes a first transformer including a first input-side coil and a first output-side coil; a second transformer including a second input-side coil and a second output-side coil; a first resistance element; a first switch that includes a first terminal, a second terminal, a third terminal, and a fourth terminal and is configured to switch between a connection configuration in which the first terminal is connected to the third terminal and the second terminal is connected to the fourth terminal and a connection configuration in which the first terminal is connected to the fourth terminal and the second terminal is connected to the third terminal; and a second switch that includes a fifth terminal, a sixth terminal, and a seventh terminal and is configured to switch between a connection configuration in which the fifth terminal is connected to the sixth terminal and a connection configuration in which the fifth terminal is connected to the seventh terminal. A first end of the first input-side coil is connected to the output end of the first amplifier; a second end of the first input-side coil is connected to the first terminal; a first end of the second input-side coil is connected to the output end of the second amplifier; a second end of the second input-side coil is connected to the third terminal; a first end of the first output-side coil is connected to the signal output terminal; a second end of the first output-side coil is connected to the second terminal; a first end of the second output-side coil is connected to the fifth terminal; a second end of the second output-side coil is connected to the fourth terminal; a first end of the first resistance element is connected to the sixth terminal; and a second end of the first resistance element and the seventh terminal are connected to the ground.

Also, an amplifier circuit according to an aspect of the present disclosure includes a first amplifier; a second amplifier; a combiner circuit configured to combine an output of the first amplifier and an output of the second amplifier; and a signal output terminal connected to the combiner circuit. The combiner circuit includes a first phase shifter that delays the phase of an input radio frequency signal by 45°; a second phase shifter that advances the phase of an input radio frequency signal by 45°; a third phase shifter that delays the phase of an input radio frequency signal by 45°; a fourth phase shifter that delays the phase of an input radio frequency signal by 45°; a fifth phase shifter that delays the phase of an input radio frequency signal by 45°; a sixth phase shifter that advances the phase of an input radio frequency signal by 45°; a first resistance element; and a first switch that includes a first terminal, a second terminal, a third terminal, a fourth terminal, a fifth terminal, and a sixth terminal and is configured to switch between a connection configuration in which the first terminal is connected to the second terminal and a connection configuration in which the first terminal is connected to the third terminal and to switch among a connection configuration in which the fourth terminal is connected to the second terminal, a connection configuration in which the fourth terminal is connected to the fifth terminal, and a connection configuration in which the fourth terminal is connected to the sixth terminal. The input end of the first phase shifter is connected to the output end of the first amplifier; the output end of the first phase shifter is connected to the first terminal; the input end of the second phase shifter is connected to the output end of the second amplifier; the output end of the second phase shifter is connected to the fourth terminal; the input end of the third phase shifter is connected to the second terminal; the output end of the third phase shifter is connected to the signal output terminal; the input end of the fourth phase shifter is connected to the third terminal; the output end of the fourth phase shifter is connected to the signal output terminal; the input end of the fifth phase shifter is connected to the fifth terminal; the output end of the fifth phase shifter is connected to the signal output terminal; the input end of the sixth phase shifter is connected to the sixth terminal; the output end of the sixth phase shifter is connected to the signal output terminal; a first end of the first resistance element is connected to the third terminal; and a second end of the first resistance element is connected to the fifth terminal.

Also, an amplifier circuit according to an aspect of the present disclosure includes a first amplifier; a second amplifier; a combiner circuit configured to combine an output of the first amplifier and an output of the second amplifier; and a signal output terminal connected to the combiner circuit. The combiner circuit includes a first transformer including a first input-side coil and a first output-side coil; a second transformer including a second input-side coil and a second output-side coil; a first resistance element; and a first switch that includes a first terminal, a second terminal, a third terminal, and a fourth terminal and is configured to switch between a connection configuration in which the first terminal is connected to the third terminal and the second terminal is connected to the fourth terminal and a connection configuration in which the first terminal is connected to the fourth terminal and the second terminal is connected to the third terminal. A first end of the first input-side coil is connected to the output end of the first amplifier; a second end of the first input-side coil is connected to the first terminal; a first end of the second input-side coil is connected to the output end of the second amplifier; a second end of the second input-side coil is connected to the third terminal; a first end of the first output-side coil is connected to the signal output terminal; a second end of the first output-side coil is connected to the second terminal; a first end of the second output-side coil is connected to the ground; and a second end of the second output-side coil is connected to the fourth terminal.

### Advantageous Effects

The present disclosure may provide a compact amplifier circuit that can operate in at least two of a differential amplification mode, a balanced amplification mode, and a Doherty amplification mode.

### BRIEF DESCRIPTION OF DRAWINGS

FIG. 1 is a circuit diagram of an amplifier circuit, a radio frequency circuit, and a communication apparatus according to a first embodiment.

FIG. 2A is a circuit state diagram of the amplifier circuit in a differential amplification mode according to the first embodiment.

FIG. 2B is a circuit state diagram of the amplifier circuit in a balanced amplification mode according to the first embodiment.

FIG. 2C is a circuit state diagram of the amplifier circuit in a Doherty amplification mode according to the first embodiment.

FIG. 3A is a graph showing amplitude deviation of the amplifier circuit in each amplification mode according to the first embodiment.

FIG. 3B is a graph showing phase deviation of the amplifier circuit in each amplification mode according to the first embodiment.

FIG. 3C is a graph showing isolation of the amplifier circuit in each amplification mode according to the first embodiment.

FIG. 4 is a plan view and a cross-sectional view of the amplifier circuit according to the first embodiment.

FIG. 5 is a circuit diagram of an amplifier circuit, a radio frequency circuit, and a communication apparatus according to a second embodiment.

FIG. 6 is a drawing illustrating examples of circuit configurations of phase shifters according to the second embodiment.

FIG. 7A is a circuit state diagram of the amplifier circuit in a differential amplification mode according to the second embodiment.

FIG. 7B is a circuit state diagram of the amplifier circuit in a balanced amplification mode according to the second embodiment.

FIG. 7C is a circuit state diagram of the amplifier circuit in a Doherty amplification mode according to the second embodiment.

FIG. 7D is a circuit state diagram of the amplifier circuit in a Doherty half amplification mode according to the second embodiment.

FIG. 8 is a plan view and a cross-sectional view of the amplifier circuit according to the second embodiment.

### DESCRIPTION OF EMBODIMENTS

Embodiments of the present disclosure are described below in detail. Each of the embodiments described below represents a general or specific example. The values, shapes, materials, components, and layouts and connection configurations of the components described in the embodiments below are just examples and are not intended to limit the present disclosure. Among the components described in the embodiments and their variations below, components not described in independent claims are optional. Also, the sizes or the ratios of sizes of components illustrated in the drawings are not necessarily accurate. In the drawings, the same reference number is assigned to substantially the same components, and overlapping descriptions of those components are omitted or simplified.

Also, in the present disclosure, terms such as “parallel” and “perpendicular” indicating relationships between elements, terms such as “rectangular” indicating shapes of elements, and numerical ranges do not only indicate their exact meanings but may also indicate substantially equivalent ranges that vary by, for example, about a few percent.

In the present disclosure, “connected” not only indicates that circuit elements are directly connected to each other using a connection terminal and/or a wire conductor but also indicates that the circuit elements are electrically connected to each other via another circuit element. Also, “connected between A and B” indicates that a component is disposed on a path connecting A to B and is connected to A and B.

Also, in the present disclosure, a plan view of a substrate indicates a view of the substrate and circuit elements mounted on the substrate that are orthographically projected onto a plane parallel to the major surface of the substrate.

Also, in the component layout of the present disclosure, “a component is disposed on or in a substrate” may indicate that the component is disposed on the major surface of the substrate or the component is disposed in the substrate. “A component is disposed on the major surface of a substrate” not only indicates that the component is disposed in contact with the major surface of the substrate but also indicates that the component is not in contact with the major surface and disposed above the major surface (for example, the component is stacked on another component disposed in contact with the major surface). Also, “a component is disposed on the major surface of a substrate” may include a layout in which the component is disposed in a recess formed in the major surface. “A component is disposed in a substrate” not only indicates that the component is encapsulated in a module substrate but also indicates a case in which the entirety of the component is disposed between two major surfaces of the substrate, but a part of the component is not covered by the substrate and a case in which only a part of the component is disposed inside of the substrate.

Also, in the present disclosure, “path” indicates a transmission line that is constituted by, for example, a wire for transmitting radio frequency signals, an electrode directly connected to the wire, and a terminal directly connected to the wire or the electrode.

Furthermore, in the present disclosure, “component A is disposed in series in path B” means that each of a signal input end and a signal output end of the component A is connected to one of a wire, an electrode, and a terminal constituting the path B.

### First Embodiment

### 1.1 Circuit Configurations of Amplifier Circuit 10, Radio Frequency Circuit 1, and Communication Apparatus 4

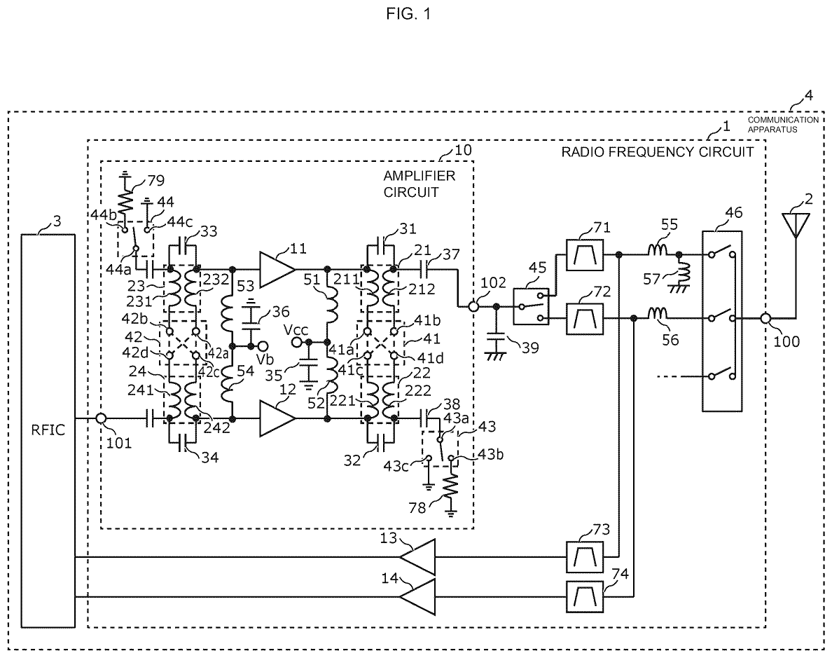

Circuit configurations of an amplifier circuit 10, a radio frequency circuit 1, and a communication apparatus 4 according to a first present embodiment are described with reference to FIG. 1. FIG. 1 is a circuit diagram of the amplifier circuit 10, the radio frequency circuit 1, and the communication apparatus 4 according to the first embodiment.

### [1.1.1 Circuit Configuration of Communication Apparatus 4]

First, a circuit configuration of the communication apparatus 4 is described. As illustrated in FIG. 1, the communication apparatus 4 according to the present embodiment includes the radio frequency circuit 1, an antenna 2, and an RF signal processing circuit (radio frequency integrated circuit: RFIC) 3.

The radio frequency circuit 1 transmits radio frequency signals between the antenna 2 and the RFIC 3. The detailed circuit configuration of the radio frequency circuit 1 is described later.

The antenna 2 is connected to an antenna connection terminal 100 of the radio frequency circuit 1 and transmits radio frequency signals output from the radio frequency circuit 1. Also, the antenna 2 receives radio frequency signals from the outside and outputs the received radio frequency signals to the radio frequency circuit 1.

The RFIC 3 is an example of a signal processing circuit that processes radio frequency signals. Specifically, the RFIC 3 performs signal processing, such as up-converting, on a transmission signal input from a baseband signal processing circuit (BBIC) and outputs a transmission signal generated by the signal processing to a transmission path of the radio frequency circuit 1. Also, the RFIC 3 performs signal processing, such as down-converting, on a reception signal input via a reception path of the radio frequency circuit 1 and outputs a reception signal generated by the signal processing to the BBIC. Moreover, the RFIC 3 includes a control unit that controls the radio frequency circuit 1. Some or all of the functions of the control unit of the RFIC 3 may be provided outside of the RFIC 3 and may be provided in, for example, the BBIC or the radio frequency circuit 1.

The RFIC 3 also functions as a control unit that controls a power supply voltage Vcc and a bias voltage Vb that are supplied to amplifiers included in the amplifier circuit 10. Specifically, the RFIC 3 outputs control signals to a power supply circuit and a bias circuit. The power supply circuit and the bias circuit may be provided in the radio frequency circuit 1 or the amplifier circuit 10. To each of amplifiers of the amplifier circuit 10, the power supply voltage Vcc controlled by the control signal is supplied from the power supply circuit, and the bias voltage Vb controlled by the control signal is supplied from the bias circuit.

Furthermore, the RFIC 3 also functions as a control unit that controls the connections of switches 41, 42, 43, 44, 45, and 46 of the radio frequency circuit 1 based on a communication band (frequency band) and an amplification mode to be used.

### [1.1.2 Circuit Configuration of Radio Frequency Circuit 1]

Next, a circuit configuration of the radio frequency circuit 1 is described. As illustrated in FIG. 1, the radio frequency circuit 1 includes the amplifier circuit 10, filters 71, 72, 73, and 74, switches 45 and 46, low-noise amplifiers 13 and 14, inductors 55, 56, and 57, a capacitor 39, and an antenna connection terminal 100.

The amplifier circuit 10 amplifies radio-frequency transmission signals (hereafter referred to as transmission signals) in a band A and a band B input from a signal input terminal 101. Instead of the amplifier circuit 10, the radio frequency circuit 1 may include a first amplifier circuit that amplifies transmission signals in the band A and a second amplifier circuit that amplifies transmission signals in the band B.

In the present disclosure, each of the band A and the band B indicates a frequency band that is predefined by, for example, a standardizing body (e.g., the Third Generation Partnership Project (3GPP, registered trademark) or the Institute of Electrical and Electronics Engineers (IEEE)) for a communication system constructed using a radio access technology (RAT). In the present embodiment, the communication system may be, for example, but is not limited to, a 4G-Long Term Evolution (LTE) system, a 5G-New Radio (NR) system, or a wireless local area network (WLAN) system.

The filter 71 is connected between the switches 45 and 46 and passes transmission signals in a transmission band of the band A (first band) out of transmission signals amplified by the amplifier circuit 10. The filter 72 is connected between the switches 45 and 46 and passes transmission signals in a transmission band of the band B (second band) out of transmission signals amplified by the amplifier circuit 10.

The filter 73 is connected between the low-noise amplifier 13 and the switch 46 and passes signals in a reception band of the band A out of reception signals received by the antenna 2. The filter 74 is connected between the low-noise amplifier 14 and the switch 46 and passes signals in a reception band of the band B out of reception signals received by the antenna 2.

Here, the filters 71 and 73 may constitute a duplexer that transmits and receives signals in the band A or may be implemented by a single filter that transmits and receives signals in the band A by Time Division Duplex (TDD). The filters 72 and 74 may constitute a duplexer that transmits and receives signals in the band B or may be implemented by a single filter that transmits and receives signals in the band B by TDD. When the filters 71 and 73 are implemented by a single filter for TDD, a switch for switching between transmission and reception is provided at least before or after the single filter. Also, when the filters 72 and 74 are implemented by a single filter for TDD, a switch for switching between transmission and reception is provided at least before or after the single filter.

The low-noise amplifier 13 is connected between the filter 73 and the RFIC 3, amplifies a reception signal in the band A, and outputs the amplified reception signal to the RFIC 3. The low-noise amplifier 14 is connected between the filter 74 and the RFIC 3, amplifies a reception signal in the band B, and outputs the amplified reception signal to the RFIC 3.

The switch 45 includes a common terminal and two selection terminals. The common terminal of the switch 45 is connected to a signal output terminal 102 of the amplifier circuit 10. One of the selection terminals of the switch 45 is connected to the filter 71, and the other one of the selection terminals is connected to the filter 72. With this connection configuration, the switch 45 connects and disconnects the signal output terminal 102 to and from the filter 71 and connects and disconnects the signal output terminal 102 to and from the filter 72.

The switch 46 is an example of an antenna switch that is connected to the antenna connection terminal 100, connects and disconnects the antenna connection terminal 100 to and from the filters 71 and 73, and connects and disconnects the antenna connection terminal 100 to and from the filters 72 and 74.

The inductor 55 is disposed in series in a path connecting the switch 46 to the filters 71 and 73. The inductor 57 is connected between the path and the ground. The inductors 55 and 57 achieve impedance matching between the switch 46 and the filters 71 and 73. The inductor 56 is disposed in series in a path connecting the switch 46 to the filters 72 and 74. The inductor 56 achieves impedance matching between the switch 46 and the filters 72 and 74. At least one of the inductors 55, 56, and 57 may be omitted.

The capacitor 39 is a circuit element for impedance matching and is connected between the ground and a path connecting the signal output terminal 102 to the switch 45. The capacitor 39 may be disposed in the amplifier circuit 10 or may be omitted.

The radio frequency circuit 1 does not have to include a reception circuit for transmitting reception signals received from the antenna 2 to the RFIC 3. In this case, the radio frequency circuit 1 does not have to include the low-noise amplifiers 13 and 14 and the filters 73 and 74.

With the above circuit configuration, the radio frequency circuit 1 can transmit and/or receive radio frequency signals in either the band A or the band B. Furthermore, the radio frequency circuit 1 can at least simultaneously transmit, simultaneously receive, or simultaneously transmit and receive radio frequency signals in the band A and the band B.

Among the components in the circuit configuration illustrated in FIG. 1, the radio frequency circuit 1 according to the present disclosure may at least include the amplifier circuit 10, the switch 45, and the filters 71 and 72.

### [1.1.3 Circuit Configuration of Amplifier Circuit 10]

Next, a circuit configuration of the amplifier circuit 10 is described in detail.

As illustrated in FIG. 1, the amplifier circuit 10 includes amplifiers 11 and 12, transformers 21, 22, 23, and 24, switches 41, 42, 43, and 44, resistance elements 78 and 79, inductors 51, 52, 53, and 54, capacitors 31, 32, 33, 34, 35, 36, 37, and 38, a signal input terminal 101, and a signal output terminal 102.

The signal input terminal 101 is connected to the RFIC 3. The signal output terminal 102 is connected to the antenna connection terminal 100 via the switches 45 and 46 and the filters 71 and 72. Here, each of the signal input terminal 101, the signal output terminal 102, and the antenna connection terminal 100 may be a metal conductor, such as a metal electrode or a metal bump, or may be a point (node) on a metal wire.

The amplifier 11 is an example of a first amplifier and is a power amplifier that amplifies a first radio frequency signal output from an output-side coil 232 of the transformer 23. The amplifier 12 is an example of a second amplifier and is a power amplifier that amplifies a second radio frequency signal output from an output-side coil 242 of the transformer 24.

Each of the amplifiers 11 and 12 includes an amplifier transistor. The amplifier transistor is, for example, a bipolar transistor, such as a heterojunction bipolar transistor (HBT), or a field-effect transistor, such as a metal-oxide-semiconductor field effect transistor (MOSFET). When the amplifier transistor is a bipolar transistor, the input end of each of the amplifiers 11 and 12 is, for example, the base terminal of the bipolar transistor, and the output end of each of the amplifiers 11 and 12 is, for example, the collector terminal of the bipolar transistor. When the amplifier transistor is a field-effect transistor, the input end of each of the amplifiers 11 and 12 is, for example, the gate terminal of the field-effect transistor, and the output end of each of the amplifiers 11 and 12 is, for example, the drain terminal of the field-effect transistor.

The transformers 21 and 22, the switches 41 and 43, the resistance element 78, and the capacitors 31, 32, 37, and 38 constitute a combiner circuit. The combiner circuit is connected between the amplifiers 11 and 12 and the signal output terminal 102 and combines an output of the amplifier 11 and an output of the amplifier 12.

The transformer 21 is an example of a first transformer and includes an input-side coil 211 (first input-side coil) and an output-side coil 212 (first output-side coil) that are electromagnetically coupled to each other. The transformer 22 is an example of a second transformer and includes an input-side coil 221 (second input-side coil) and an output-side coil 222 (second output-side coil) that are electromagnetically coupled to each other.

The switch 41 is an example of a first switch and includes a terminal 41a (first terminal), a terminal 41b (second terminal), a terminal 41c (third terminal), and a terminal 41d (fourth terminal). The switch 41 is a double pole double throw (DPDT) switch that can switch between (1) a connection configuration in which the terminal 41a is connected to the terminal 41c and the terminal 41b is connected to the terminal 41d and (2) a connection configuration in which the terminal 41a is connected to the terminal 41d and the terminal 41b is connected to the terminal 41c. Alternatively, the switch 41 may be a switch circuit constituted by, for example, multiple single pole single throw (SPST) switches or single pole double throw (SPDT) switches.

The switch 43 is an example of a second switch and includes a terminal 43a (fifth terminal), a terminal 43b (sixth terminal), and a terminal 43c (seventh terminal). The switch 43 is an SPDT switch that can switch between a connection configuration in which the terminal 43a is connected to the terminal 43b and a connection configuration in which the terminal 43a is connected to the terminal 43c. Alternatively, the switch 43 may be a switch circuit constituted by, for example, multiple SPST switches.

The resistance element 78 is an example of a first resistance element and is connected between the switch 43 and the ground.

A first end of the input-side coil 211 is connected to the output end of the amplifier 11, and a second end of the input-side coil 211 is connected to the terminal 41a. A first end of the input-side coil 221 is connected to the output end of the amplifier 12, and a second end of the input-side coil 221 is connected to the terminal 41c.

A first end of the output-side coil 212 is connected to the signal output terminal 102 via the capacitor 37, and a second end of the output-side coil 212 is connected to the terminal 41b. A first end of the output-side coil 222 is connected to the terminal 43a via the capacitor 38, and a second end of the output-side coil 222 is connected to the terminal 41d.

A first end of the resistance element 78 is connected to the terminal 43b, and a second end of the resistance element 78 and the terminal 43c are connected to the ground.

The capacitor 37 is a DC-block capacitor connected between the first end of the output-side coil 212 and the signal output terminal 102. The capacitor 38 is a DC-block capacitor connected between the first end of the output-side coil 222 and the terminal 43a.

The capacitor 31 is an example of a first capacitor and is connected between the first end of the input-side coil 211 and the first end of the output-side coil 212. The capacitor 31 adjusts the degree of impedance matching between the input-side coil 211 and the output-side coil 212.

The capacitor 32 is an example of a second capacitor and is connected between the first end of the input-side coil 221 and the first end of the output-side coil 222. The capacitor 32 adjusts the degree of impedance matching between the input-side coil 221 and the output-side coil 222.

The transformers 23 and 24, the switches 42 and 44, the resistance element 79, and the capacitors 33 and 34 constitute a splitter circuit. The splitter circuit is connected between the signal input terminal 101 and the amplifiers 11 and 12, splits a radio frequency signal input from the signal input terminal 101 into a first radio frequency signal and a second radio frequency signal, outputs the first radio frequency signal to the amplifier 11, and outputs the second radio frequency signal to the amplifier 12.

The transformer 23 is an example of a third transformer and includes an input-side coil 231 (third input-side coil) and an output-side coil 232 (third output-side coil) that are electromagnetically coupled to each other. The transformer 24 is an example of a fourth transformer and includes an input-side coil 241 (fourth input-side coil) and an output-side coil 242 (fourth output-side coil) that are electromagnetically coupled to each other.

The switch 42 is an example of a third switch and includes a terminal 42b (eighth terminal), a terminal 42a (ninth terminal), a terminal 42d (tenth terminal), and a terminal 42c (eleventh terminal). The switch 42 is a DPDT switch that can switch between (1) a connection configuration in which the terminal 42b is connected to the terminal 42d and the terminal 42a is connected to the terminal 42c and (2) a connection configuration in which the terminal 42b is connected to the terminal 42c and the terminal 42a is connected to the terminal 42d. Alternatively, the switch 42 may be a switch circuit constituted by, for example, multiple SPST switches or SPDT switches.

The switch 44 is an example of a fourth switch and includes a terminal 44a (twelfth terminal), a terminal 44b (thirteenth terminal), and a terminal 44c (fourteenth terminal). The switch 44 is an SPDT switch that can switch between a connection configuration in which the terminal 44a is connected to the terminal 44b and a connection configuration in which the terminal 44a is connected to the terminal 44c. Alternatively, the switch 44 may be a switch circuit constituted by, for example, multiple SPST switches.

The resistance element 79 is an example of a second resistance element and is connected between the switch 44 and the ground.

A first end of the input-side coil 231 is connected to the terminal 44a via a capacitor, and a second end of the input-side coil 231 is connected to the terminal 42b. A first end of the input-side coil 241 is connected to the signal input terminal 101, and a second end of the input-side coil 241 is connected to the terminal 42d.

A first end of the output-side coil 232 is connected to the input end of the amplifier 11, and a second end of the output-side coil 232 is connected to the terminal 42a. A first end of the output-side coil 242 is connected to the input end of the amplifier 12, and a second end of the output-side coil 242 is connected to the terminal 42c.

A first end of the resistance element 79 is connected to the terminal 44b, and a second end of the resistance element 79 and the terminal 44c are connected to the ground.

The capacitor 33 is connected between the first end of the input-side coil 231 and the first end of the output-side coil 232 and adjusts the degree of impedance matching between the input-side coil 231 and the output-side coil 232. The capacitor 34 is connected between the first end of the input-side coil 241 and the first end of the output-side coil 242 and adjusts the degree of impedance matching between the input-side coil 241 and the output-side coil 242.

The splitter circuit is not necessarily constituted by the transformers 23 and 24, the switches 42 and 44, the resistance element 79, and the capacitors 33 and 34. The splitter circuit may be any type of circuit that distributes the power of a radio frequency signal input from the signal input terminal 101 into a first radio frequency signal and a second radio frequency signal at a predetermined distribution ratio and changes the phase of the first radio frequency signal and the phase of the second radio frequency signal.

The amplifier circuit 10 further includes a power supply voltage terminal to which a power supply voltage Vcc is supplied. The inductor 51 is an example of a first inductor and is connected between the output end of the amplifier 11 and the power supply voltage terminal. The inductor 52 is an example of a second inductor and is connected between the output end of the amplifier 12 and the power supply voltage terminal. The inductor 51 is a choke coil that reduces the leakage of the output signal and the radio frequency noise of the amplifier 11 into the power supply voltage terminal. The inductor 52 is a choke coil that reduces the leakage of the output signal and the radio frequency noise of the amplifier 12 into the power supply voltage terminal. The capacitor 35 is a bypass capacitor connected between the power supply voltage terminal and the ground.

In a related-art amplifier circuit not including the switch 41, the power supply voltage Vcc is supplied to the amplifier 11 via the input-side coil 211 and is also supplied to the amplifier 12 via the input-side coil 221. On the other hand, in the amplifier circuit 10 according to the present embodiment, because the switch 41 is connected between the input-side coils 211 and 221, the power supply voltage Vcc cannot be stably supplied to the amplifier 11 via the input-side coil 211 and cannot be stably supplied to the amplifier 12 via the input-side coil 221. For this reason, in the amplifier circuit 10 according to the present embodiment, the inductors 51 and 52 for supplying the power supply voltage Vcc to the amplifiers 11 and 12 are additionally provided so that the power supply voltage Vcc can be stably supplied to the amplifiers 11 and 12.

The amplifier circuit 10 further includes a bias voltage terminal to which a bias voltage Vb is supplied. The inductor 53 is connected between the input end of the amplifier 11 and the bias voltage terminal. The inductor 54 is connected between the input end of the amplifier 12 and the bias voltage terminal. The inductor 53 is a choke coil that reduces the leakage of the first radio frequency signal and the radio frequency noise into the bias voltage terminal. The inductor 54 is a choke coil that reduces the leakage of the second radio frequency signal and the radio frequency noise into the bias voltage terminal. The capacitor 36 is a bypass capacitor connected between the bias voltage terminal and the ground.

Alternatively, each of the inductors 51 to 54 may be a transmission line that passes DC components and blocks predetermined frequency components.

In a related-art amplifier circuit not including the switch 42, the bias voltage Vb is supplied to the amplifier 11 via the output-side coil 232 and is also supplied to the amplifier 12 via the output-side coil 242. On the other hand, in the amplifier circuit 10 according to the present embodiment, because the switch 42 is connected between the output-side coils 232 and 242, the bias voltage Vb cannot be stably supplied to the amplifier 11 via the output-side coil 232 and cannot be stably supplied to the amplifier 12 via the output-side coil 242. For this reason, in the amplifier circuit 10 according to the present embodiment, the inductors 53 and 54 for supplying the bias voltage Vb to the amplifiers 11 and 12 are additionally provided so that the bias voltage Vb can be stably supplied to the amplifiers 11 and 12.

With the above configuration, by changing the connection configurations of the switches 41 to 44, the amplifier circuit 10 can selectively operate in (1) a differential amplification mode in which the phase difference between a signal output from the amplifier 11 and a signal output from the amplifier 12 is 180°; (2) a balanced amplification mode in which the phase difference between a signal output from the amplifier 11 and a signal output from the amplifier 12 is 90°; or (3) a Doherty amplification mode in which the amplifier 11 is a carrier amplifier, the amplifier 12 is a peak amplifier, and the phase difference between a signal output from the amplifier 11 and a signal output from the amplifier 12 is 90°. Thus, the present embodiment makes it possible to provide a compact amplifier circuit 10 that can operate in the differential amplification mode, the balanced amplification mode, and the Doherty amplification mode.

An amplifier circuit according to a variation of the amplifier circuit 10 of the present embodiment may have a configuration in which the switches 43 and 44 and the resistance elements 78 and 79 included in the amplifier circuit 10 are omitted, and the first end of the output-side coil 222 and the first end of the input-side coil 231 are connected to the ground.

In other words, the amplifier circuit according to the variation of the first embodiment includes the amplifiers 11 and 12, a combiner circuit that combines an output of the amplifier 11 and an output of the amplifier 12, and the signal output terminal 102 connected to the combiner circuit. The combiner circuit according to the variation includes the transformers 21 and 22 and the switch 41. In the combiner circuit, the first end of the input-side coil 211 is connected to the output end of the amplifier 11, the second end of the input-side coil 211 is connected to the terminal 41a, the first end of the input-side coil 221 is connected to the output end of the amplifier 12, the second end of the input-side coil 221 is connected to the terminal 41c, the first end of the output-side coil 212 is connected to the signal output terminal 102, the second end of the output-side coil 212 is connected to the terminal 41b, the first end of the output-side coil 222 is connected to the ground, and the second end of the output-side coil 222 is connected to the terminal 41d.

With this configuration, by changing the connection configurations of the switch 41, the single amplifier circuit according to the variation can operate in (1) a differential amplification mode in which the phase difference between a signal output from the amplifier 11 and a signal output from the amplifier 12 is 180° and (2) a Doherty amplification mode in which the amplifier 11 is a carrier amplifier, the amplifier 12 is a peak amplifier, and the phase difference between a signal output from the amplifier 11 and a signal output from the amplifier 12 is 90°. Thus, this variation makes it possible to provide a compact amplifier circuit that can operate in the differential amplification mode and the Doherty amplification mode.

When the amplifier circuit according to the variation operates in the differential amplification mode in which the phase difference between a signal output from the amplifier 11 and a signal output from the amplifier 12 is 180°, the terminal 41a is connected to the terminal 41c, and the terminal 41b is connected to the terminal 41d. On the other hand, in the Doherty amplification mode in which the amplifier 11 is a carrier amplifier, the amplifier 12 is a peak amplifier, and the phase difference between a signal output from the amplifier 11 and a signal output from the amplifier 12 is 90°, the terminal 41a is connected to the terminal 41d, and the terminal 41b is connected to the terminal 41c.

### [1.1.4 Amplification Modes of Amplifier Circuit 10]

Next, the features of amplification modes in which the amplifier circuit 10 is operable are described.

### (Differential Amplification Mode)

In the differential amplification mode, the phase difference between an output signal of the amplifier 11 and an output signal of the amplifier 12 is 180°. The amplifiers 11 and 12 both operate in class AB (or class A). In the differential amplification mode, because the phase difference between two output signals is 180°, noise components of the two output signals can be accurately removed, and the adjacent channel leakage power ratio (ACLR) can be improved. Also, ideally, this mode can remove even harmonic waves and is therefore suitable for broadband applications. Furthermore, because the transformer 22 is not connected to the resistance element 78, signal transmission loss due to the resistance element 78 can be prevented, and the peak efficiency is improved. On the other hand, this mode is vulnerable to load variation.

### (Balanced Amplification Mode)

In the balanced amplification mode, the phase difference between an output signal of the amplifier 11 and an output signal of the amplifier 12 is 90°. The amplifiers 11 and 12 both operate in class AB (or class A). In the balanced amplification mode, because the phase difference between two output signals is 90°, even if the impedance of a load connected to the signal output terminal 102 varies, it is possible to stably output an output signal obtained by combining the two output signals from the signal output terminal 102. For example, when the output impedance of one of the amplifiers 11 and 12 changes to high impedance due to load variation, the output impedance of the other one of the amplifiers 11 and 12 changes to low impedance due to the load variation. Therefore, by combining the output signals of the amplifiers 11 and 12 with the combiner circuit, it is possible to mutually offset power fluctuations in the output signals resulting from the load variation. Thus, the balanced amplification mode can make the power of a signal output from the signal output terminal 102 substantially constant without being influenced by load variation. That is, operating the amplifier circuit 10 in the balanced amplification mode makes the amplifier circuit 10 resistant to load variation. On the other hand, because the transformer 22 is connected to the resistance element 78, signal transmission loss occurs at the resistance element 78, and the peak efficiency may be reduced.

### (Doherty Amplification Mode)

In the Doherty amplification mode, the phase difference between an output signal of the amplifier 11 and an output signal of the amplifier 12 is 90°. The amplifier 11 is a carrier amplifier and operates in class AB (or class A), and the amplifier 12 is a peak amplifier and operates in class C. The amplifier 11 performs amplification operation for all power levels of the first radio frequency signal and can efficiently perform amplification operation particularly in a low power range and a middle power range. The amplifier 12 performs amplification operation in a range in which the power level of the second radio frequency signal is high. The output impedance of the amplifier 12 decreases as the power level of the second radio frequency signal increases. Accordingly, when the amplifier circuit 10 is operated in the Doherty amplification mode, the efficiency of the amplifier circuit 10 is high at a power level (back-off range) at which the amplifier 12 is turned off. On the other hand, because the amplifier 12 operates in class C, ACLR may be degraded.

### [1.1.5 Circuit Connection States of Amplifier Circuit 10 for Implementing Respective Amplification Modes]

Next, circuit connection states of the amplifier circuit 10 for implementing the differential amplification mode, the balanced amplification mode, and the Doherty amplification mode are described.

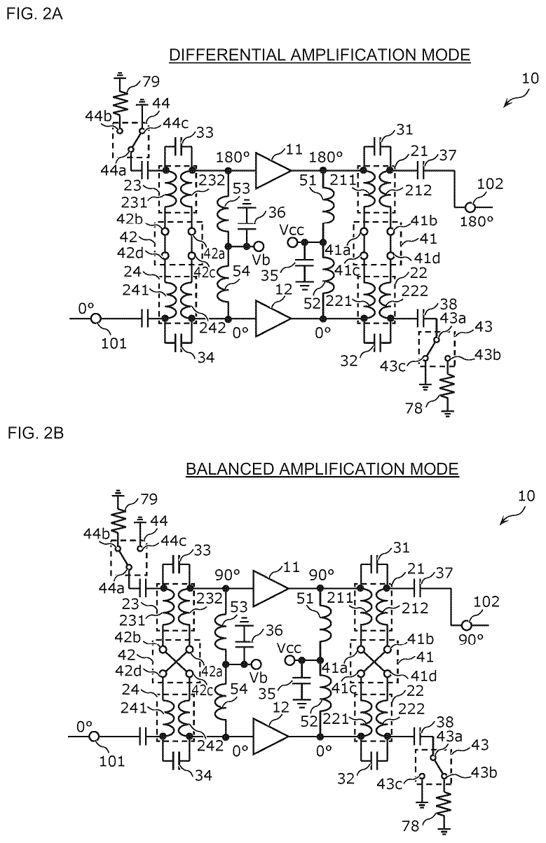

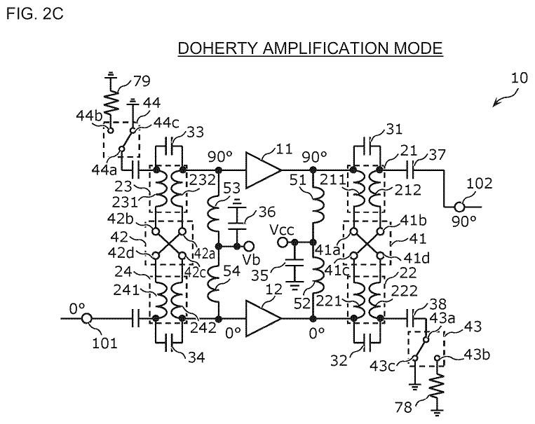

FIG. 2A is a circuit state diagram of the amplifier circuit 10 in the differential amplification mode according to the first embodiment. In the differential amplification mode illustrated in FIG. 2A, in the combiner circuit, the terminal 41a is connected to the terminal 41c, the terminal 41b is connected to the terminal 41d, and the terminal 43a is connected to the terminal 43c. Also, in the splitter circuit, the terminal 42a is connected to the terminal 42c, the terminal 42b is connected to the terminal 42d, and the terminal 44a is connected to the terminal 44c.

With the above connection configuration, the combiner circuit functions as a balanced-unbalanced conversion element (balun) in which the first end of the input-side coil 211 serves as a first balanced signal input end, the first end of the input-side coil 221 serves as a second balanced signal input end, and the first end of the output-side coil 212 serves as an unbalanced signal output end. The balun of the combiner circuit converts two balanced signals with a phase difference of 180° into one unbalanced signal. Also, the splitter circuit functions as a balun in which the first end of the input-side coil 241 serves as an unbalanced signal input end, the first end of the output-side coil 242 serves as a first balanced signal output end, and the first end of the output-side coil 232 serves as a second balanced signal output end. The balun of the splitter circuit converts an unbalanced signal into two balanced signals with a phase difference of 180°.

As illustrated in FIG. 2A, in the differential amplification mode, the phase difference between an output signal of the amplifier 11 and an output signal of the amplifier 12 is 180°.

In this mode, the amplifier circuit 10 can improve ACLR, achieve broadband operation, and improve peak efficiency.

FIG. 2B is a circuit state diagram of the amplifier circuit 10 in the balanced amplification mode according to the first embodiment. In the balanced amplification mode illustrated in FIG. 2B, in the combiner circuit, the terminal 41a is connected to the terminal 41d, the terminal 41b is connected to the terminal 41c, and the terminal 43a is connected to the terminal 43b. Also, in the splitter circuit, the terminal 42a is connected to the terminal 42d, the terminal 42b is connected to the terminal 42c, and the terminal 44a is connected to the terminal 44b.

With the above connection configuration, the combiner circuit functions as a 90-degree hybrid circuit including an isolation terminal to which the resistance element 78 is connected. The 90-degree hybrid circuit of the combiner circuit converts two balanced input signals with a phase difference of 90° into one unbalanced output signal. Also, the splitter circuit functions as a 90-degree hybrid circuit including an isolation terminal to which the resistance element 79 is connected. The 90-degree hybrid circuit of the splitter circuit converts an unbalanced input signal into two balanced output signals with a phase difference of 90°.

As illustrated in FIG. 2B, in the balanced amplification mode, the phase difference between an output signal of the amplifier 11 and an output signal of the amplifier 12 is 90°.

This makes it possible to provide the amplifier circuit 10 that is resistant to load variation.

FIG. 2C is a circuit state diagram of the amplifier circuit 10 in the Doherty amplification mode according to the first embodiment. In the Doherty amplification mode illustrated in FIG. 2C, in the combiner circuit, the terminal 41a is connected to the terminal 41d, the terminal 41b is connected to the terminal 41c, and the terminal 43a is connected to the terminal 43c. Also, in the splitter circuit, the terminal 42a is connected to the terminal 42d, the terminal 42b is connected to the terminal 42c, and the terminal 44a is connected to the terminal 44c.

With the above connection configuration, the combiner circuit functions as a 90-degree hybrid circuit including an isolation terminal that is grounded. The 90-degree hybrid circuit of the combiner circuit converts two balanced input signals with a phase difference of 90° into one unbalanced output signal. Also, the splitter circuit functions as a 90-degree hybrid circuit including an isolation terminal that is grounded. The 90-degree hybrid circuit of the splitter circuit converts an unbalanced input signal into two balanced output signals with a phase difference of 90°.

As illustrated in FIG. 2C, in the Doherty amplification mode, the phase difference between an output signal of the amplifier 11 and an output signal of the amplifier 12 is 90°.

This makes it possible to provide the amplifier circuit 10 with high backoff efficiency.

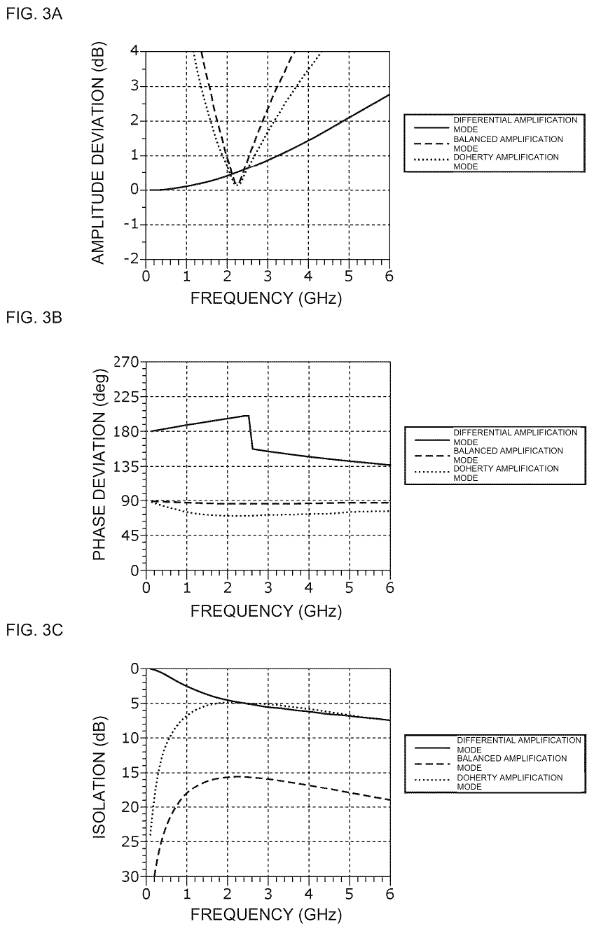

FIG. 3A is a graph showing amplitude deviation of the amplifier circuit 10 in each amplification mode according to the first embodiment. FIG. 3B is a graph showing phase deviation of the amplifier circuit 10 in each amplification mode according to the first embodiment. FIG. 3C is a graph showing isolation of the amplifier circuit 10 in each amplification mode according to the first embodiment.

As shown in FIG. 3A, the amplitude deviation between an output signal of the amplifier 11 and an output signal of the amplifier 12 is small over a wide frequency range in the differential amplification mode. On the other hand, in the balanced amplification mode, although the amplitude deviation can be reduced only in a narrow frequency range, as illustrated in FIG. 3C, isolation can be improved over a wide frequency range.

In consideration of the characteristics of the amplification modes described above, mode selection is performed as described below.

### (First Mode Selection)

When the amplifier circuit 10 is operated in an envelope tracking (ET) mode in which the power supply voltage Vcc supplied to the amplifiers 11 and 12 is varied according to the envelope signals of radio frequency signals input to the amplifiers 11 and 12, the differential amplification mode or the balanced amplification mode is selected. On the other hand, when the amplifier circuit 10 is operated in an average power tracking (APT) mode in which the power supply voltage Vcc supplied to the amplifiers 11 and 12 is varied according to the average output power of radio frequency signals output from the amplifiers 11 and 12, the Doherty amplification mode is selected.

This makes it possible to improve load variation tolerance or peak efficiency in the ET mode and makes it possible to improve backoff efficiency in the APT mode.

### (Second Mode Selection)

When a radio frequency signal in the band A and a radio frequency signal in the band B are simultaneously amplified by the amplifier circuit 10, the balanced amplification mode or the Doherty amplification mode is selected. When only one of a radio frequency signal in the band A and a radio frequency signal in the band B is amplified by the amplifier circuit 10, the differential amplification mode is selected.

When a radio frequency signal in the band A and a radio frequency signal in the band B are transmitted simultaneously, this configuration makes it possible to improve load variation tolerance or backoff efficiency.

### (Third Mode Selection)

When the amplifier circuit 10 is operated in a low power mode, the Doherty amplification mode is selected; and when the amplifier circuit 10 is operated in a high power mode, the differential amplification mode or the balanced amplification mode is selected.

This makes it possible to improve load variation tolerance or peak efficiency in the high power mode and makes it possible to improve backoff efficiency in the low power mode.

The low power mode is a mode in which the maximum output power of the amplifier circuit 10 is relatively low and is, for example, a mode that has a maximum output power less than the maximum output power permitted in Power Class 3. Also, the high power mode is a mode in which the maximum output power of the amplifier circuit 10 is relatively high and is, for example, a mode that has a maximum output power greater than or equal to the maximum output power permitted in Power Class 3.

Power Class is a classification of the output power of UE, which is defined by, for example, maximum output power. A smaller value of Power Class indicates higher permitted output power. For example, in 3GPP (registered trademark), the maximum output power permitted in Power Class 1 is 31 dBm, the maximum output power permitted in Power Class 1.5 is 29 dBm, the maximum output power permitted in Power Class 2 is 26 dBm, and the maximum output power permitted in Power Class 3 is 23 dBm.

### 1.2 Layout of Components of Amplifier Circuit 10

Next, the layout of components of the amplifier circuit 10 according to the present embodiment is described.

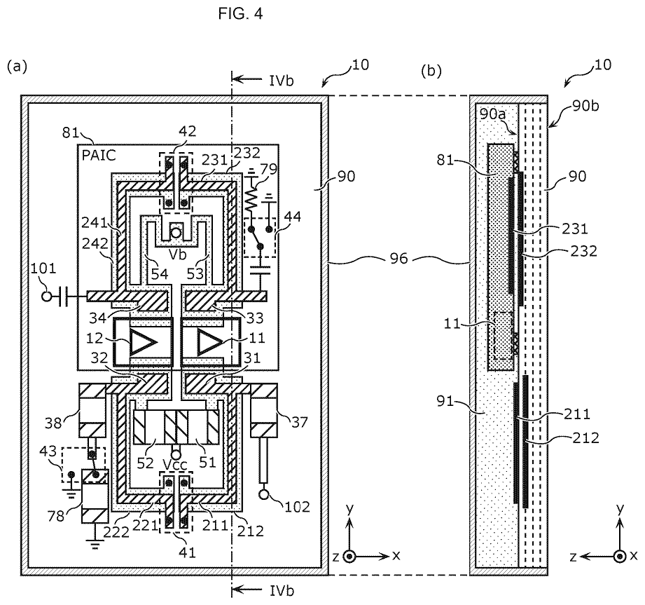

FIG. 4 is a plan view and a cross-sectional view of the amplifier circuit 10 according to the first embodiment. FIG. 4 (a) illustrates the layout of circuit components as seen through a major surface 90a of a module substrate 90 from the positive z-axis direction. FIG. 4 (b) is a cross-sectional view taken along line IVb-IVb in FIG. 4 (a). In FIG. 4, the illustration of some of wires connecting the module substrate 90 and circuit components are omitted.

In addition to the components of the amplifier circuit 10 illustrated in FIG. 1, the amplifier circuit 10 illustrated in FIG. 4 includes the module substrate 90, a resin component 91, and a shield electrode layer 96.

The module substrate 90 has major surfaces 90a and 90b facing each other. Circuit components constituting the amplifier circuit 10 are mounted on the module substrate 90. The module substrate 90 is implemented by, for example, a low temperature co-fired ceramics (LTCC) substrate with a multilayer structure formed of multiple dielectric layers, a high temperature co-fired ceramics (HTCC) substrate, a component-embedded board, a substrate including a redistribution layer (RDL), or a printed circuit board.

The resin component 91 is disposed on the major surface 90a, covers some of multiple circuit components and the major surface 90a, and has a function to ensure the reliability, such as mechanical strength and moisture resistance, of the multiple circuit components.

The shield electrode layer 96 covers the front and side surfaces of the resin component 91 and is set at the ground potential. This improves the function to shield electromagnetic fields from external circuits.

As illustrated in FIG. 4, the amplifiers 11 and 12, the input-side coils 211, 221, 231, and 241, the output-side coils 212, 222, 232, and 242, the switches 41 to 44, the resistance elements 78 and 79, the inductors 51 to 54, the capacitors 31 to 34, 37, and 38, the signal input terminal 101, and the signal output terminal 102 are laid out on the major surface 90a of the module substrate 90.

As illustrated in FIG. 4 (a), the input-side coils 231 and 241, the output-side coils 232 and 242, the switches 42 and 44, the resistance element 79, the inductors 53 and 54, the capacitors 33 and 34, and the signal input terminal 101, which are connected to the input side of the amplifiers 11 and 12, are disposed in a region above the amplifiers 11 and 12 on the module substrate 90 (a region in the positive y-axis direction in FIG. 4).

Also, the input-side coils 211 and 221, the output-side coils 212 and 222, the switches 41 and 43, the resistance element 78, the inductors 51 and 52, the capacitors 31, 32, 37, and 38, and the signal output terminal 102, which are connected to the output side of the amplifiers 11 and 12, are disposed in a region below the amplifiers 11 and 12 on the module substrate 90 (a region in the negative y-axis direction in FIG. 4).

The layout described above makes it possible to shorten the wires connecting circuit elements and thereby reduce the signal transmission loss of the amplifier circuit 10.

The amplifiers 11 and 12, the input-side coils 231 and 241, the switches 42 and 44, the resistance element 79, and the capacitors 33 and 34 are included in a semiconductor IC 81. The semiconductor IC 81 is disposed on or over the major surface 90a.

The semiconductor IC 81 is implemented by using, for example, a complementary metal oxide semiconductor (CMOS). Specifically, the semiconductor IC 81 may be manufactured by a Silicon on Insulator (SOI) process. Also, the semiconductor IC 81 may be comprised of at least one of GaAs, SiGe, and GaN. However, semiconductor materials of the semiconductor IC 81 are not limited to those described above.

The above configuration makes it possible to reduce the size of the amplifier circuit 10 and reduce the signal transmission loss on the input side of the amplifiers 11 and 12.

A control circuit, e.g., part of the semiconductor IC for controlling the switches 41 to 44 may be provided on the major surface 90b of the module substrate 90. Furthermore, the low-noise amplifiers 13 and 14 and the switches 45 and 46 of the radio frequency circuit 1 may be disposed on the major surface 90b.

The input-side coil 231 is implemented by a wire conductor formed in the semiconductor IC 81. The output-side coil 232 is implemented by a wire conductor formed on the major surface 90a and is disposed to overlap the input-side coil 231 in plan view of the major surface 90a.

The input-side coil 241 is implemented by a wire conductor formed on the semiconductor IC 81. The output-side coil 242 is implemented by a wire conductor formed on the major surface 90a and is disposed to overlap the input-side coil 241 in plan view of the major surface 90a.

The above configuration makes it possible to reduce the size of the transformers 23 and 24.

Alternatively, the input-side coils 231 and 241 may be formed on or in the module substrate 90 instead of in the semiconductor IC 81.

The switches 42 and 44 may be formed on the major surface 90b instead of in the semiconductor IC 81. Furthermore, the switches 42 and 44 may be included, together with the control circuit, in a semiconductor IC disposed on the major surface 90b. In this case, the semiconductor IC including the switches 42 and 44 and the control circuit may at least partially overlap the amplifiers 11 and 12 in plan view of the major surfaces 90a and 90b. This configuration makes it possible to shorten wires connecting the amplifiers 11 and 12 to the switches 42 and 44 and thereby makes it possible to reduce the signal transmission loss on the input side of the amplifiers 11 and 12.

The capacitor 33 is implemented by a conductor wire formed in the semiconductor IC 81 and a wire formed on the major surface 90a. The capacitor 34 is implemented by a conductor wire formed in the semiconductor IC 81 and a wire formed on the major surface 90a.

The inductors 53 and 54 are formed on or in the module substrate 90. The capacitors 35 and 36 may be either formed in the semiconductor IC 81 or formed on or in the module substrate 90.

Each of the input-side coil 211 and the output-side coil 212 is implemented by a wire conductor formed on or in the module substrate 90. The input-side coil 211 and the output-side coil 212 are formed in different layers of the module substrate 90 and are disposed to overlap each other in plan view of the major surface 90a.

Each of the input-side coil 221 and the output-side coil 222 is implemented by a wire conductor formed on or in the module substrate 90. The input-side coil 221 and the output-side coil 222 are formed in different layers of the module substrate 90 and are disposed to overlap each other in plan view of the major surface 90a.

The above configuration makes it possible to reduce the size of the transformers 21 and 22.

The switches 41 and 43 are, for example, surface mount devices (SMD) and are disposed on the major surface 90a. Alternatively, the switches 41 and 43 may be disposed on the major surface 90b. Furthermore, the switches 41 and 43 may be included, together with the control circuit, in a semiconductor IC disposed on the major surface 90b. In this case, the semiconductor IC including the switches 41 and 43 and the control circuit may at least partially overlap the amplifiers 11 and 12 in plan view of the major surfaces 90a and 90b. This configuration makes it possible to shorten wires connecting the amplifiers 11 and 12 to the switches 41 and 43 and thereby makes it possible to reduce the signal transmission loss on the output side of the amplifiers 11 and 12.

The capacitor 31 is implemented by a conductor wire formed in the semiconductor IC 81 and a wire formed on the major surface 90a. The capacitor 32 is implemented by a conductor wire formed in the semiconductor IC 81 and a wire formed on the major surface 90a.

The inductors 51 and 52, the capacitors 37 and 38, and the resistance element 78 are, for example, SMDs and are disposed on the major surface 90a. Alternatively, the inductors 51 and 52, the capacitors 37 and 38, and the resistance element 78 may be implemented by conductor wires formed on or in the module substrate 90.

### 1.3 Effects

The amplifier circuit 10 according to the present embodiment includes the amplifiers 11 and 12, the combiner circuit configured to combine an output of the amplifier 11 and an output of the amplifier 12, and the signal output terminal 102 connected to the combiner circuit. The combiner circuit includes the transformer 21 including the input-side coil 211 and the output-side coil 212; the transformer 22 including the input-side coil 221 and the output-side coil 222; the resistance element 78; the switch 41 that includes the terminals 41a, 41b, 41c, and 41d and is configured to switch between a connection configuration in which the terminal 41a is connected to the terminal 41c and the terminal 41b is connected to the terminal 41d and a connection configuration in which the terminal 41a is connected to the terminal 41d and the terminal 41b is connected to the terminal 41c; and the switch 43 that includes the terminals 43a, 43b, and 43c and is configured to switch between a connection configuration in which the terminal 43a is connected to the terminal 43b and a connection configuration in which the terminal 43a is connected to the terminal 43c. The first end of the input-side coil 211 is connected to the output end of the amplifier 11, the second end of the input-side coil 211 is connected to the terminal 41a, the first end of the input-side coil 221 is connected to the output end of the amplifier 12, the second end of the input-side coil 221 is connected to the terminal 41c, the first end of the output-side coil 212 is connected to the signal output terminal 102, the second end of the output-side coil 212 is connected to the terminal 41b, the first end of the output-side coil 222 is connected to the terminal 43a, the second end of the output-side coil 222 is connected to the terminal 41d, the first end of the resistance element 78 is connected to the terminal 43b, and the second end of the resistance element 78 and the terminal 43c are connected to the ground.

With this configuration, by changing the connection configurations of the switches 41 and 43, the amplifier circuit 10 can selectively operate in (1) the differential amplification mode, (2) the balanced amplification mode, or (3) the Doherty amplification mode. Thus, this configuration makes it possible to provide a compact amplifier circuit 10 that can operate in the differential amplification mode, the balanced amplification mode, and the Doherty amplification mode.

Also, for example, the amplifier circuit 10 further includes the inductors 51 and 52 and a power supply voltage terminal. The first end of the inductor 51 is connected to the output end of the amplifier 11 and the first end of the input-side coil 211, the first end of the inductor 52 is connected to the output end of the amplifier 12 and the first end of the input-side coil 221, and the second end of the inductor 51 and the second end of the inductor 52 are connected to the power supply voltage terminal.

With this configuration, because the inductors 51 and 52 for supplying the power supply voltage Vcc to the amplifiers 11 and 12 are provided separately from the transformers 21 and 22, it is possible to stably supply the power supply voltage Vcc to the amplifiers 11 and 12.

Also, for example, the amplifier circuit 10 further includes the capacitors 31 and 32, the first end of the capacitor 31 is connected to the first end of the input-side coil 211, the second end of the capacitor 31 is connected to the first end of the output-side coil 212, the first end of the capacitor 32 is connected to the first end of the input-side coil 221, and the second end of the capacitor 32 is connected to the first end of the output-side coil 222.

This configuration makes it possible to optimize the amplitude deviation, the phase deviation, and the isolation in each amplification mode by adjusting the constants of the capacitors 31 and 32.

Also, for example, in the differential amplification mode of the amplifier circuit 10, the terminal 41a is connected to the terminal 41c, the terminal 41b is connected to the terminal 41d, and the terminal 43a is connected to the terminal 43c. In the balanced amplification mode, the terminal 41a is connected to the terminal 41d, the terminal 41b is connected to the terminal 41c, and the terminal 43a is connected to the terminal 43b. In the Doherty amplification mode, the terminal 41a is connected to the terminal 41d, the terminal 41b is connected to the terminal 41c, and the terminal 43a is connected to the terminal 43c.

This configuration makes it possible to implement three amplification modes by changing the connection configurations of the switches 41 and 43 and thereby makes it possible to simplify the amplifier circuit 10.

Also, for example, when the amplifier circuit 10 is operated in the ET mode, the differential amplification mode or the balanced amplification mode is selected; and when the amplifier circuit 10 is operated in the APT mode, the Doherty amplification mode is selected.

This configuration makes it possible to improve load variation tolerance or peak efficiency in the ET mode and to improve backoff efficiency in the APT mode.

Also, for example, when the first radio frequency signal in the band A and the second radio frequency signal in the band B are simultaneously amplified by the amplifier circuit 10, the balanced amplification mode or the Doherty amplification mode is selected. When only one of the first radio frequency signal and the second radio frequency signal is amplified by the amplifier circuit 10, the differential amplification mode is selected.

When a radio frequency signal in the band A and a radio frequency signal in the band B are transmitted simultaneously, this configuration makes it possible to improve load variation tolerance or backoff efficiency.

Also, for example, when the amplifier circuit 10 is operated in the low power mode, the Doherty amplification mode is selected; and when the amplifier circuit 10 is operated in the high power mode, the differential amplification mode or the balanced amplification mode is selected.

This makes it possible to improve load variation tolerance or peak efficiency in the high power mode and makes it possible to improve backoff efficiency in the low power mode.

Also, for example, the amplifier circuit 10 further includes the signal input terminal 101 and the splitter circuit configured to split a radio frequency signal input from the signal input terminal 101 into two radio frequency signals and output the two radio frequency signals to the amplifiers 11 and 12, respectively. The splitter circuit includes the transformer 23 including the input-side coil 231 and the output-side coil 232; the transformer 24 including the input-side coil 241 and the output-side coil 242; the resistance element 79; the switch 42 including the terminals 42a, 42b, 42c, and 42d and configured to switch between a connection configuration in which the terminal 42a is connected to the terminal 42c and the terminal 42b is connected to the terminal 42d and a connection configuration in which the terminal 42a is connected to the terminal 42d and the terminal 42b is connected to the terminal 42c; and a switch 44 including the terminals 44a, 44b, and 44c and configured to switch between a connection configuration in which the terminal 44a is connected to the terminal 44b and a connection configuration in which the terminal 44a is connected to the terminal 44c. The first end of the input-side coil 231 is connected to the terminal 44a, the second end of the input-side coil 231 is connected to the terminal 42b, the first end of the input-side coil 241 is connected to the signal input terminal 101, the second end of the input-side coil 241 is connected to the terminal 42d, the first end of the output-side coil 232 is connected to the input end of the amplifier 11, the second end of the output-side coil 232 is connected to the terminal 42a, the first end of the output-side coil 242 is connected to the input end of the amplifier 12, the second end of the output-side coil 242 is connected to the terminal 42c, the first end of the resistance element 79 is connected to the terminal 44b, and the second end of the resistance element 79 and the terminal 44c are connected to the ground.

With this configuration, the splitter circuit can change the phases of radio frequency signals input to the amplifiers 11 and 12 by changing the connection configurations of the switches 42 and 44.

The amplifier circuit according to a variation of the present embodiment includes the amplifiers 11 and 12, a combiner circuit configured to combine an output of the amplifier 11 and an output of the amplifier 12, and the signal output terminal 102 connected to the combiner circuit. The combiner circuit according to the variation includes the transformers 21 and 22 and the switch 41. In the combiner circuit, the first end of the input-side coil 211 is connected to the output end of the amplifier 11, the second end of the input-side coil 211 is connected to the terminal 41a, the first end of the input-side coil 221 is connected to the output end of the amplifier 12, the second end of the input-side coil 221 is connected to the terminal 41c, the first end of the output-side coil 212 is connected to the signal output terminal 102, the second end of the output-side coil 212 is connected to the terminal 41b, the first end of the output-side coil 222 is connected to the ground, and the second end of the output-side coil 222 is connected to the terminal 41d.

With this configuration, the single amplifier circuit according to the variation can selectively operate in (1) the differential amplification mode or (2) the Doherty amplification mode by changing the connection configuration of the switch 41. Thus, this variation makes it possible to provide a compact amplifier circuit that can operate in the differential amplification mode and the Doherty amplification mode.

Also, for example, in the differential amplification mode of the amplifier circuit according to the variation, the terminal 41a is connected to the terminal 41c, and the terminal 41b is connected to the terminal 41d. On the other hand, in the Doherty amplification mode, the terminal 41a is connected to the terminal 41d, and the terminal 41b is connected to the terminal 41c.

This configuration makes it possible to implement two amplification modes by changing the connection configuration of the switch 41 and thereby makes it possible to simplify the amplifier circuit.

### Second Embodiment

The first embodiment presents the amplifier circuit 10 in which each of the combiner circuit and the splitter circuit is implemented by transformers and switches. A second embodiment presents an amplifier circuit 10A in which each of a combiner circuit and a splitter circuit is implemented by phase shifters and switches.

### 2.1 Circuit Configurations of Amplifier Circuit 10A, Radio Frequency Circuit 1A, and Communication Apparatus 4A

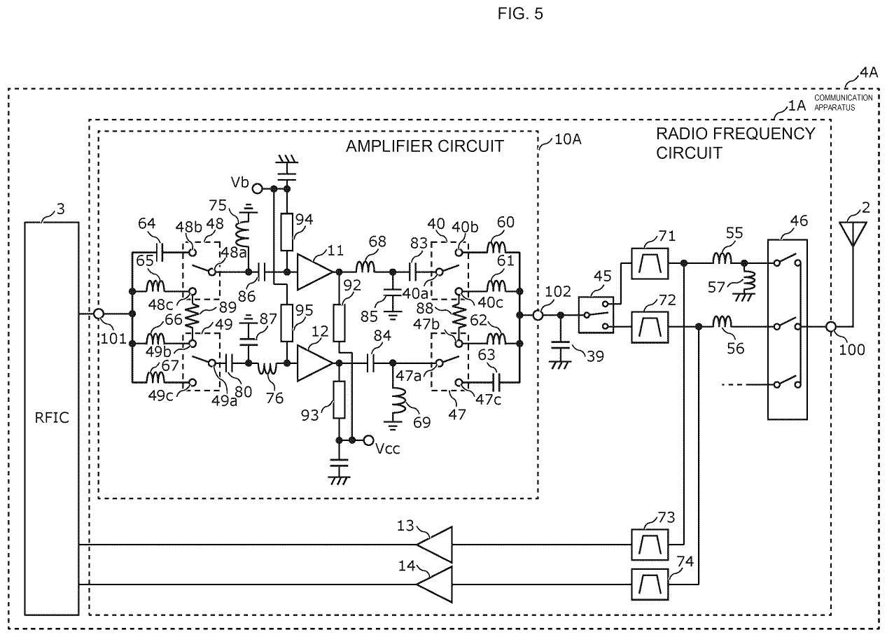

Circuit configurations of the amplifier circuit 10A, a radio frequency circuit 1A, and a communication apparatus 4A according to the present embodiment are described with reference to FIG. 5. FIG. 5 is a circuit diagram of the amplifier circuit 10A, the radio frequency circuit 1A, and the communication apparatus 4A according to the second embodiment.

### [2.1.1 Circuit Configuration of Communication Apparatus 4A]

First, a circuit configuration of the communication apparatus 4A is described. As illustrated in FIG. 5, the communication apparatus 4A according to the present embodiment includes the radio frequency circuit 1A, an antenna 2, and an RFIC 3. The communication apparatus 4A according to the present embodiment differs from the communication apparatus 4 according to the first embodiment only in the configuration of the radio frequency circuit 1A. Therefore, descriptions of the antenna 2 and the RFIC 3 of the communication apparatus 4A of the present embodiment are omitted, and the configuration of the radio frequency circuit 1A is mainly described below.

The radio frequency circuit 1A transmits radio frequency signals between the antenna 2 and the RFIC 3.

### [2.1.2 Circuit Configuration of Radio Frequency Circuit 1A]

As illustrated in FIG. 5, the radio frequency circuit 1A includes the amplifier circuit 10A, filters 71, 72, 73, and 74, switches 45 and 46, low-noise amplifiers 13 and 14, inductors 55, 56, and 57, a capacitor 39, and an antenna connection terminal 100. The radio frequency circuit 1A according to the present embodiment differs from the radio frequency circuit 1 according to the first embodiment only in the configuration of the amplifier circuit 10A. Therefore, the radio frequency circuit 1A is described below focusing on the configuration of the amplifier circuit 10A.

The amplifier circuit 10A amplifies transmission signals in the band A and the band B input from a signal input terminal 101.

Among the components in the circuit configuration illustrated in FIG. 5, the radio frequency circuit 1A may at least include the amplifier circuit 10A, the switch 45, and the filters 71 and 72.

### [2.1.3 Circuit Configuration of Amplifier Circuit 10A]

Next, a circuit configuration of the amplifier circuit 10A is described in detail.

As illustrated in FIG. 5, the amplifier circuit 10A includes amplifiers 11 and 12, inductors 60, 61, 62, 65, 66, 67, 68, 69, 75, and 76, capacitors 63, 64, 80, 83, 84, 85, 86, and 87, switches 40, 47, 48, and 49, resistance elements 88 and 89, a signal input terminal 101, and a signal output terminal 102.

The signal input terminal 101 is connected to the RFIC 3. The signal output terminal 102 is connected to the antenna connection terminal 100 via the switches 45 and 46 and the filters 71 and 72. Here, each of the signal input terminal 101, the signal output terminal 102, and the antenna connection terminal 100 may be a metal conductor, such as a metal electrode or a metal bump, or may be a point (node) on a metal wire.

The amplifiers 11 and 12 have the same configurations as those of the amplifiers 11 and 12 according to the first embodiment. Therefore, descriptions of the configurations of the amplifiers 11 and 12 are omitted.

The inductors 60, 61, 62, 68, and 69, the capacitors 63, 83, 84, and 85, the switches 40 and 47, and the resistance element 88 constitute a combiner circuit. The combiner circuit is connected between the amplifiers 11 and 12 and the signal output terminal 102 and combines an output of the amplifier 11 and an output of the amplifier 12.

The combination of the inductor 68 and the capacitor 85 is an example of a first phase shifter that delays the phase of an input radio frequency signal by 45°. The inductor 68 is an example of a first inductor and is connected between the output end of the amplifier 11 and a terminal 40a (first terminal) of the switch 40 (first switch). The capacitor 85 is an example of a first capacitor and is connected between the ground and a path connecting the inductor 68 to the terminal 40a. The inductor 68 and the capacitor 85 constitute a low pass filter. A first end of the inductor 68 is the input end of the first phase shifter, and a connection point between the inductor 68 and the capacitor 85 is the output end of the first phase shifter.

The combination of the capacitor 84 and the inductor 69 is an example of a second phase shifter that advances the phase of an input radio frequency signal by 45°. The capacitor 84 is an example of a second capacitor and is connected between the output end of the amplifier 12 and a terminal 47a (fourth terminal) of the switch 47 (first switch). The inductor 69 is an example of a second inductor and is connected between the ground and a path connecting the capacitor 84 to the terminal 47a. The capacitor 84 and the inductor 69 constitute a high pass filter. A first end of the capacitor 84 is the input end of the second phase shifter, and a connection point between the capacitor 84 and the inductor 69 is the output end of the second phase shifter.

The inductor 60 is an example of a third phase shifter that delays the phase of an input radio frequency signal by 45°. The inductor 60 is an example of a third inductor and is connected between a terminal 40b (second terminal) of the switch 40 (first switch) and the signal output terminal 102. A first end of the inductor 60 is the input end of the third phase shifter, and a second end of the inductor 60 is the output end of the third phase shifter.

The inductor 61 is an example of a fourth phase shifter that delays the phase of an input radio frequency signal by 45°. The inductor 61 is an example of a fourth inductor and is connected between a terminal 40c (third terminal) of the switch 40 (first switch) and the signal output terminal 102. A first end of the inductor 61 is the input end of the fourth phase shifter, and a second end of the inductor 61 is the output end of the fourth phase shifter.

The inductor 62 is an example of a fifth phase shifter that delays the phase of an input radio frequency signal by 45°. The inductor 62 is an example of a fifth inductor and is connected between a terminal 47b (fifth terminal) of the switch 47 (first switch) and the signal output terminal 102. A first end of the inductor 62 is the input end of the fifth phase shifter, and a second end of the inductor 62 is the output end of the fifth phase shifter.

The capacitor 63 is an example of a sixth phase shifter that advances the phase of an input radio frequency signal by 45°. The capacitor 63 is an example of a third capacitor and is connected between a terminal 47c (sixth terminal) of the switch 47 (first switch) and the signal output terminal 102. A first end of the capacitor 63 is the input end of the sixth phase shifter, and a second end of the capacitor 63 is the output end of the sixth phase shifter.

The combination of the switches 40 and 47 is an example of a first switch and includes the terminal 40a (first terminal), the terminal 40b (second terminal), the terminal 40c (third terminal), the terminal 47a (fourth terminal), the terminal 47b (fifth terminal), and the terminal 47c (sixth terminal). The combination of the switches 40 and 47 is a Double Pole 4 Throw (DP4T) switch that can (1) switch between a connection configuration in which the terminal 40a is connected to the terminal 40b and a connection configuration in which the terminal 40a is connected to the terminal 40c; and (2) switch among a connection configuration in which the terminal 47a is connected to the terminal 40b, a connection configuration in which the terminal 47a is connected to the terminal 47b, and a connection configuration in which the terminal 47a is connected to the terminal 47c. Alternatively, the combination of the switches 40 and 47 may be a switch circuit including (1) an SPDT switch that includes the terminals 40a, 40b, and 40c and switches between a connection configuration in which the terminal 40a is connected to the terminal 40b and a connection configuration in which the terminal 40a is connected to the terminal 40c; and (2) a single pole 3 throw (SP3T) switch that includes the terminals 47a, 40b, 47b, and 47c and switches among a connection configuration in which the terminal 47a is connected to the terminal 40b, a connection configuration in which the terminal 47a is connected to the terminal 47b, and a connection configuration in which the terminal 47a is connected to the terminal 47c.

The resistance element 88 is an example of a first resistance element and is connected between the inductor 61 and the inductor 62.

A first end of the inductor 68 is connected to the output end of the amplifier 11, and a connection point between the inductor 68 and the capacitor 85 is connected to the terminal 40a.

A first end of the capacitor 84 is connected to the output end of the amplifier 12, and a connection point between the capacitor 84 and the inductor 69 is connected to the terminal 47a.

A first end of the inductor 60 is connected to the terminal 40b, and a second end of the inductor 60 is connected to the signal output terminal 102.

A first end of the inductor 61 is connected to the terminal 40c, and a second end of the inductor 61 is connected to the signal output terminal 102.

A first end of the inductor 62 is connected to the terminal 47b, and a second end of the inductor 62 is connected to the signal output terminal 102.

A first end of the capacitor 63 is connected to the terminal 47c, and a second end of the capacitor 63 is connected to the signal output terminal 102.

A first end of the resistance element 88 is connected to the terminal 40c, and a second end of the resistance element 88 is connected to the terminal 47b.

The capacitor 83 is a DC-block capacitor that is connected between the signal output terminal 102 and a connection point between the inductor 68 and the capacitor 85.

The inductors 65, 66, 67, 75, and 76, the capacitors 64, 80, 86, and 87, the switches 48 and 49, and the resistance element 89 constitute a splitter circuit. The splitter circuit is connected between the signal input terminal 101 and the amplifiers 11 and 12 and splits a radio frequency signal input from the signal input terminal 101 into a first radio frequency signal and a second radio frequency signal, outputs the first radio frequency signal to the amplifier 11, and outputs the second radio frequency signal to the amplifier 12.

The combination of the capacitor 86 and the inductor 75 is an example of a seventh phase shifter that advances the phase of an input radio frequency signal by 45°. The capacitor 86 is connected between a terminal 48a (seventh terminal) of the switch 48 (second switch) and the input end of the amplifier 11. The inductor 75 is connected between the ground and a path connecting the capacitor 86 to the terminal 48a. The capacitor 86 and the inductor 75 constitute a high pass filter. The connection point between a first end of the capacitor 86 and the inductor 75 is the input end of the seventh phase shifter, and a second end of the capacitor 86 is the output end of the seventh phase shifter.

The combination of the inductor 76 and the capacitor 87 is an example of an eighth phase shifter that delays the phase of an input radio frequency signal by 45°. The inductor 76 is connected between a terminal 49a (tenth terminal) of the switch 49 (second switch) and the input end of the amplifier 12. The capacitor 87 is connected between the ground and a path connecting the inductor 76 to the terminal 49a. The inductor 76 and the capacitor 87 constitute a low pass filter. The connection point between a first end of the inductor 76 and the capacitor 87 is the input end of the eighth phase shifter, and a second end of the inductor 76 is the output end of the eighth phase shifter.

The capacitor 64 is an example of a ninth phase shifter and advances the phase of an input radio frequency signal by 45°. The capacitor 64 is connected between the signal input terminal 101 and a terminal 48b (eighth terminal) of the switch 48 (second switch). A first end of the capacitor 64 is the input end of the ninth phase shifter, and a second end of the capacitor 64 is the output end of the ninth phase shifter.

The inductor 65 is an example of a tenth phase shifter that delays the phase of an input radio frequency signal by 45°. The inductor 65 is connected between the signal input terminal 101 and a terminal 48c (ninth terminal) of the switch 48 (second switch). A first end of the inductor 65 is the input end of the tenth phase shifter, and a second end of the inductor 65 is the output end of the tenth phase shifter.

The inductor 66 is an example of an eleventh phase shifter that delays the phase of an input radio frequency signal by 45°. The inductor 66 is connected between the signal input terminal 101 and a terminal 49b (eleventh terminal) of the switch 49 (second switch). A first end of the inductor 66 is the input end of the eleventh phase shifter, and a second end of the inductor 66 is the output end of the eleventh phase shifter.

The inductor 67 is an example of a twelfth phase shifter that delays the phase of an input radio frequency signal by 45°. The inductor 67 is connected between the signal input terminal 101 and a terminal 49c (twelfth terminal) of the switch 49 (second switch). A first end of the inductor 67 is the input end of the twelfth phase shifter, and a second end of the inductor 67 is the output end of the twelfth phase shifter.

The combination of the switches 48 and 49 is an example of a second switch and includes the terminal 48a (seventh terminal), the terminal 48b (eighth terminal), the terminal 48c (ninth terminal), the terminal 49a (tenth terminal), the terminal 49b (eleventh terminal), and the terminal 49c (twelfth terminal). The combination of the switches 48 and 49 is a DP4T switch that can (1) switch among a connection configuration in which the terminal 48a is connected to the terminal 49c, a connection configuration in which the terminal 48a is connected to the terminal 48b, and a connection configuration in which the terminal 48a is connected to the terminal 48c; and (2) switch between a connection configuration in which the terminal 49a is connected to the terminal 49b and a connection configuration in which the terminal 49a is connected to the terminal 49c. Alternatively, the combination of the switches 48 and 49 may be a switch circuit including (1) an SP3T switch that includes the terminals 48a, 48b, 48c, and 49c and switches among a connection configuration in which the terminal 48a is connected to the terminal 49c, a connection configuration in which the terminal 48a is connected to the terminal 48b, and a connection configuration in which the terminal 48a is connected to the terminal 48c; and (2) an SPDT switch that includes the terminals 48a, 48b, and 48c and switches between a connection configuration in which the terminal 49a is connected to the terminal 49b and a connection configuration in which the terminal 49a is connected to the terminal 49c.

The resistance element 89 is an example of a second resistance element and is connected between the inductor 65 and the inductor 66.

The connection point between the first end of the capacitor 86 and the inductor 75 is connected to the terminal 48a, and the second end of the capacitor 86 is connected to the input end of the amplifier 11.

The connection point between the first end of the inductor 76 and the capacitor 87 is connected to the terminal 49a, and the second end of the inductor 76 is connected to the input end of the amplifier 12.

The first end of the capacitor 64 is connected to the signal input terminal 101, and the second end of the capacitor 64 is connected to the terminal 48b.

The first end of the inductor 65 is connected to the signal input terminal 101, and the second end of the inductor 65 is connected to the terminal 48c.

The first end of the inductor 66 is connected to the signal input terminal 101, and the second end of the inductor 66 is connected to the terminal 49b.

The first end of the inductor 67 is connected to the signal input terminal 101, and the second end of the inductor 67 is connected to the terminal 49c.

The first end of the resistance element 89 is connected to the terminal 48c, and the second end of the resistance element 89 is connected to the terminal 49b.

The capacitor 80 is a DC-block capacitor that is connected between the terminal 49a and a connection point between the inductor 76 and the capacitor 87.

The splitter circuit does not have to be constituted by the inductors 65, 66, 67, 75, and 76, the capacitors 64, 80, 86, and 87, the switches 48 and 49, and the resistance element 89. The splitter circuit may be any type of phase shifting circuit that distributes the power of a radio frequency signal input from the signal input terminal 101 into a first radio frequency signal and a second radio frequency signal at a predetermined distribution ratio and changes the phase of the first radio frequency signal and the phase of the second radio frequency signal.

The amplifier circuit 10A further includes a power supply voltage terminal to which the power supply voltage Vcc is supplied. A phase shift line 92 is connected between the output end of the amplifier 11 and the power supply voltage terminal. A phase shift line 93 is connected between the output end of the amplifier 12 and the power supply voltage terminal. The phase shift line 92 is a choke coil that reduces the leakage of the output signal and the radio frequency noise of the amplifier 11 into the power supply voltage terminal. The phase shift line 93 is a choke coil that reduces the leakage of the output signal and the radio frequency noise of the amplifier 12 into the power supply voltage terminal.

The amplifier circuit 10A further includes a bias voltage terminal to which the bias voltage Vb is supplied. A phase shift line 94 is connected between the output end of the amplifier 11 and the bias voltage terminal. A phase shift line 95 is connected between the output end of the amplifier 12 and the bias voltage terminal. The phase shift line 94 is a choke coil that reduces the leakage of the first radio frequency signal and the radio frequency noise into the bias voltage terminal. The phase shift line 95 is a choke coil that reduces the leakage of the second radio frequency signal and the radio frequency noise into the bias voltage terminal.

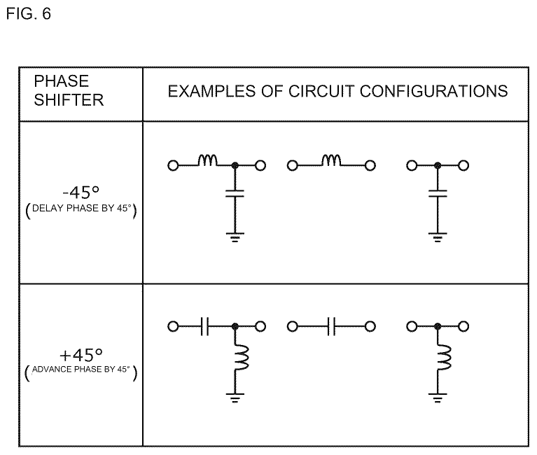

Each of the first through twelfth phase shifters does not have to be implemented by circuit elements as described above. FIG. 6 is a drawing illustrating examples of circuit configurations of phase shifters according to the second embodiment.

In the amplifier circuit 10A according to the present embodiment, each of the first phase shifter, the third phase shifter, the fourth phase shifter, the fifth phase shifter, the eighth phase shifter, the tenth phase shifter, the eleventh phase shifter, and the twelfth phase shifter, which delays the phase of an input radio frequency signal by 45°, may have any of the circuit configurations illustrated in the upper row of FIG. 6.

That is, each of the first phase shifter, the third phase shifter, the fourth phase shifter, the fifth phase shifter, the eighth phase shifter, the tenth phase shifter, the eleventh phase shifter, and the twelfth phase shifter may have, for example, (1) a low pass filter configuration in which an inductor is disposed in series, and a capacitor is connected between a series arm and the ground; (2) a configuration in which an inductor is disposed in series; or (3) a configuration in which a capacitor is connected between a series arm and the ground.

Also, in the amplifier circuit 10A according to the present embodiment, each of the second phase shifter, the sixth phase shifter, the seventh phase shifter, and the ninth phase shifter, which advances the phase of an input radio frequency signal by 45°, may have any of the circuit configurations illustrated in the lower row of FIG. 6. That is, each of the second phase shifter, the sixth phase shifter, the seventh phase shifter, and the ninth phase shifter may have, for example, (1) a high pass filter configuration in which a capacitor is disposed in series, and an inductor is connected between a series arm and the ground, (2) a configuration in which a capacitor is disposed in series, or (3) a configuration in which an inductor is connected between a series arm and the ground.

Each of the first phase shifter, the third phase shifter, the fourth phase shifter, the fifth phase shifter, the eighth phase shifter, the tenth phase shifter, the eleventh phase shifter, and the twelfth phase shifter does not have to be configured to delay the phase of an input radio frequency signal by exactly 45° but may be a circuit configured to delay the phase of an input radio frequency signal by 45°+10°.

Each of the second phase shifter, the sixth phase shifter, the seventh phase shifter, and the ninth phase shifter does not have to be configured to advance the phase of an input radio frequency signal by exactly 45° but may be a circuit configured to advance the phase of an input radio frequency signal by 45°+10°.

### [2.1.4 Circuit Connection States of Amplifier Circuit 10A for Implementing Respective Amplification Modes]

The amplifier circuit 10A according to the present embodiment can operate in the differential amplification mode, the balanced amplification mode, and the Doherty amplification mode described in the first embodiment. In addition to the above three amplification modes, the amplifier circuit 10A can operate in a Doherty half amplification mode. Below, circuit connection states of the amplifier circuit 10A of the present embodiment for implementing the above four amplification modes are described.

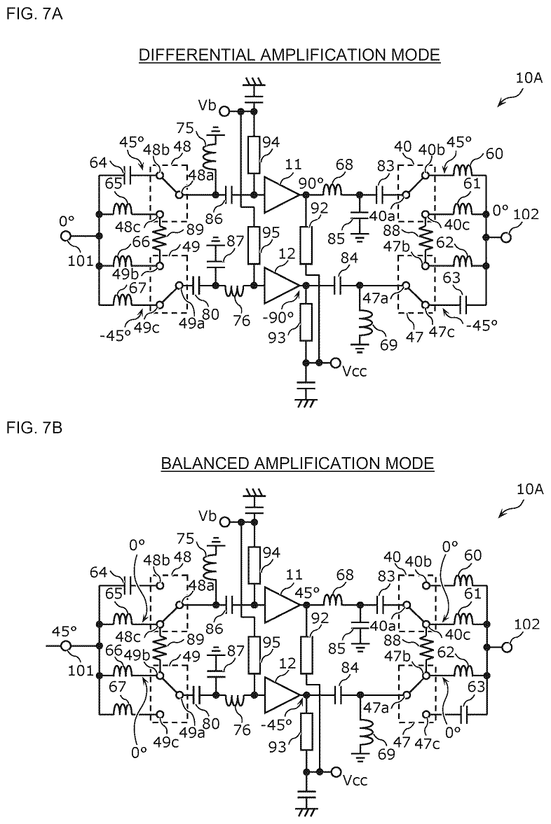

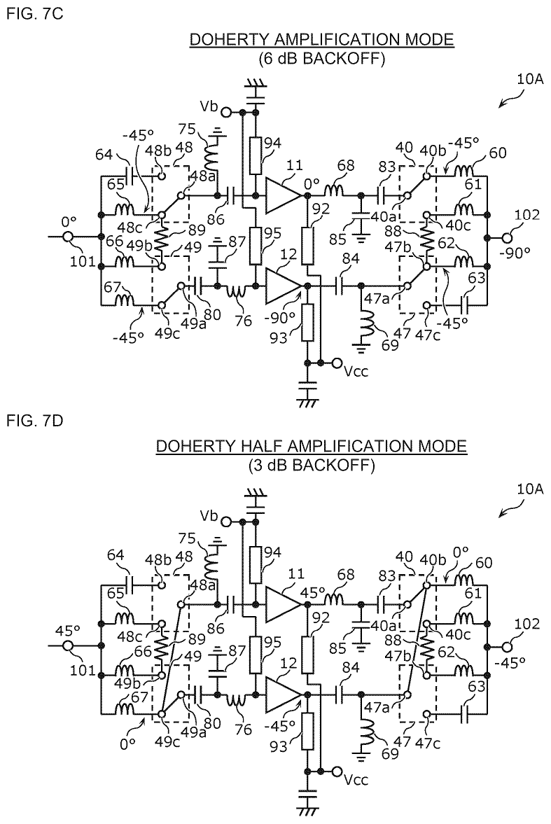

FIG. 7A is a circuit state diagram of the amplifier circuit 10A in the differential amplification mode according to the second embodiment. In the differential amplification mode illustrated in FIG. 7A, in the combiner circuit, the terminal 40a is connected to the terminal 40b, and the terminal 47a is connected to the terminal 47c. Also, in the splitter circuit, the terminal 48a is connected to the terminal 48b, and the terminal 49a is connected to the terminal 49c.

With the above connection configuration, for example, when a radio frequency signal with a phase of 0° is input to the signal input terminal 101, the output signal of the amplifier 11 is a radio frequency signal with a phase of 90°, and the output signal of the amplifier 12 is a radio frequency signal with a phase of −90°. These output signals are combined by the combiner circuit, and a radio frequency signal with a phase of 0° is output from the signal output terminal 102. That is, as illustrated in FIG. 7A, in the differential amplification mode, the phase difference between the output signal of the amplifier 11 and the output signal of the amplifier 12 is 180°.

In this mode, the amplifier circuit 10A can improve ACLR, achieve broadband operation, and improve peak efficiency.

FIG. 7B is a circuit state diagram of the amplifier circuit 10A in the balanced amplification mode according to the second embodiment. In the balanced amplification mode illustrated in FIG. 7B, in the combiner circuit, the terminal 40a is connected to the terminal 40c, and the terminal 47a is connected to the terminal 47b. Also, in the splitter circuit, the terminal 48a is connected to the terminal 48c, and the terminal 49a is connected to the terminal 49b.

With the above connection configuration, for example, when a radio frequency signal with a phase of 45° is input to the signal input terminal 101, the output signal of the amplifier 11 is a radio frequency signal with a phase of 45°, and the output signal of the amplifier 12 is a radio frequency signal with a phase of −45°. These output signals are combined by the combiner circuit, and a radio frequency signal with a phase of 0° is output from the signal output terminal 102. That is, as illustrated in FIG. 7B, in the balanced amplification mode, the phase difference between the output signal of the amplifier 11 and the output signal of the amplifier 12 is 90°.

This makes it possible to provide the amplifier circuit 10A that is resistant to load variation.

FIG. 7C is a circuit state diagram of the amplifier circuit 10A in the Doherty amplification mode according to the second embodiment. In the Doherty amplification mode illustrated in the FIG. 7C, in the combiner circuit, the terminal 40a is connected to the terminal 40b, and the terminal 47a is connected to the terminal 47b. Also, in the splitter circuit, the terminal 48a is connected to the terminal 48c, and the terminal 49a is connected to the terminal 49c.

With the above connection configuration, for example, when a radio frequency signal with a phase of 0° is input to the signal input terminal 101, the output signal of the amplifier 11 is a radio frequency signal with a phase of 0°, and the output signal of the amplifier 12 is a radio frequency signal with a phase of −90°. These output signals are combined by the combiner circuit, and a radio frequency signal with a phase of −90° is output from the signal output terminal 102. That is, in the Doherty amplification mode, as illustrated in FIG. 7C, the phase difference between the output signal of the amplifier 11 and the output signal of the amplifier 12 is 90°.

This makes it possible to provide the amplifier circuit 10A with high efficiency at 6 dB backoff.

FIG. 7D is a circuit state diagram of the amplifier circuit 10A in the Doherty half amplification mode according to the second embodiment. In the Doherty half amplification mode illustrated in FIG. 7D, in the combiner circuit, the terminal 40a is connected to the terminal 40b, and the terminal 47a is connected to the terminal 40b. Also, in the splitter circuit, the terminal 48a is connected to the terminal 49c, and the terminal 49a is connected to the terminal 49c.

With the above connection configuration, for example, when a radio frequency signal with a phase of 45° (a phase of 0° at the terminal 49c) is input to the signal input terminal 101, the output signal of the amplifier 11 is a radio frequency signal with a phase of 45°, and the output signal of the amplifier 12 is a radio frequency signal with a phase of −45°. These output signals are combined by the combiner circuit, and a radio frequency signal with a phase of −45° (a phase of 0° at the terminal 40b) is output from the signal output terminal 102. That is, in the Doherty half amplification mode, as illustrated in FIG. 7D, the phase difference between the output signal of the amplifier 11 and the output signal of the amplifier 12 is 90°.

This makes it possible to provide the amplifier circuit 10A with high efficiency at 3 dB backoff.

In consideration of the characteristics of the amplification modes described above, mode selection is performed as described below.

### (First Mode Selection)

When the amplifier circuit 10A is operated in the ET mode in which the power supply voltage Vcc supplied to the amplifiers 11 and 12 is varied according to the envelope signals of radio frequency signals input to the amplifiers 11 and 12, the differential amplification mode or the balanced amplification mode is selected. On the other hand, when the amplifier circuit 10A is operated in the APT mode in which the power supply voltage Vcc supplied to the amplifiers 11 and 12 is varied according to the average output power of radio frequency signals output from the amplifiers 11 and 12, the Doherty amplification mode or the Doherty half amplification mode is selected.

This configuration makes it possible to improve load variation tolerance or peak efficiency in the ET mode and to improve backoff efficiency in the APT mode.

### (Second Mode Selection)

When a radio frequency signal in the band A and a radio frequency signal in the band B are simultaneously amplified by the amplifier circuit 10A, the balanced amplification mode, the Doherty amplification mode, or the Doherty half amplification mode is selected. When only one of a radio frequency signal in the band A and a radio frequency signal in the band B is amplified by the amplifier circuit 10A, the differential amplification mode is selected.

When a radio frequency signal in the band A and a radio frequency signal in the band B are transmitted simultaneously, this configuration makes it possible to improve load variation tolerance or backoff efficiency.

### (Third Mode Selection)

When the amplifier circuit 10A is operated in a low power mode, the Doherty amplification mode or the Doherty half amplification mode is selected; and when the amplifier circuit 10A is operated in a high power mode, the differential amplification mode or the balanced amplification mode is selected.

This makes it possible to improve load variation tolerance or peak efficiency in the high power mode and makes it possible to improve backoff efficiency in the low power mode.

### 2.2 Layout of Components of Amplifier Circuit 10A

Next, the layout of components of the amplifier circuit 10A according to the present embodiment is described.

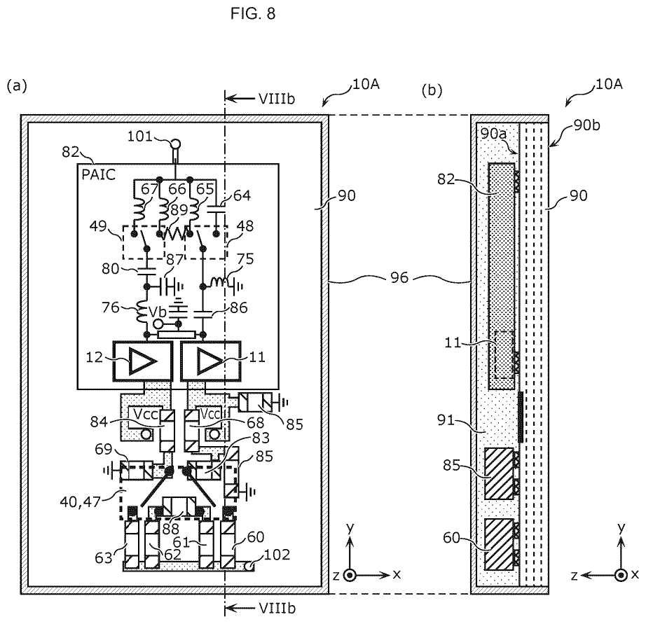

FIG. 8 is a plan view and a cross-sectional view of the amplifier circuit 10A according to the second embodiment. FIG. 8 (a) illustrates the layout of circuit components as seen through a major surface 90a of a module substrate 90 from the positive z-axis direction. FIG. 8 (b) is a cross-sectional view taken along line VIIIb-VIIIb in FIG. 8 (a). In FIG. 8, the illustration of some of wires connecting the module substrate 90 and circuit components are omitted.

In addition to the components of the amplifier circuit 10A illustrated in FIG. 5, the amplifier circuit 10A illustrated in FIG. 8 includes the module substrate 90, a resin component 91, and a shield electrode layer 96.

The module substrate 90, the resin component 91, and the shield electrode layer 96 are the same as the module substrate 90, the resin component 91, and the shield electrode layer 96 of the amplifier circuit 10 according to the first embodiment. Therefore, descriptions of these components are omitted.

As illustrated in FIG. 8, the amplifiers 11 and 12, the inductors 60, 61, 62, 65, 66, 67, 68, 69, 75, and 76, the capacitors 63, 64, 80, 83, 84, 85, 86, and 87, the switches 40, 47, 48, and 49, the resistance elements 88 and 89, the signal input terminal 101, and the signal output terminal 102 are laid out on the major surface 90a of the module substrate 90.

As illustrated in FIG. 8 (a), the inductors 65, 66, 67, 75, and 76, the capacitors 64, 80, 86, and 87, the switches 48 and 49, the resistance element 89, and the signal input terminal 101, which are connected to the input side of the amplifiers 11 and 12, are disposed in a region above the amplifiers 11 and 12 on the module substrate 90 (a region in the positive y-axis direction in FIG. 8). Also, the inductors 60, 61, 62, 68, and 69, the capacitors 63, 83, 84, and 85, the switches 40 and 47, the resistance element 88, and the signal output terminal 102, which are connected to the output side of the amplifiers 11 and 12, are disposed in a region below the amplifiers 11 and 12 on the module substrate 90 (a region in the negative y-axis direction in FIG. 8).

The layout described above makes it possible to shorten the wires connecting circuit elements and thereby reduce the signal transmission loss of the amplifier circuit 10A.

The amplifiers 11 and 12, the inductors 65, 66, 67, 75, and 76, the capacitors 64, 80, 86, and 87, the switches 48 and 49, and the resistance element 89 are included in a semiconductor IC 82. The semiconductor IC 82 is disposed on or over the major surface 90a.

The semiconductor IC 82 is implemented by using, for example, a CMOS. Specifically, the semiconductor IC 82 may be manufactured by an SOI process. Also, the semiconductor IC 82 may be comprised of at least one of GaAs, SiGe, and GaN. However, semiconductor materials of the semiconductor IC 82 are not limited to those described above.

The above configuration makes it possible to reduce the size of the amplifier circuit 10A and reduce the signal transmission loss on the input side of the amplifiers 11 and 12.

A control circuit for controlling the switches 40, 47, 48, and 49 may be provided on a major surface 90b of the module substrate 90. Furthermore, the low-noise amplifiers 13 and 14 and the switches 45 and 46 of the radio frequency circuit 1A may be disposed on the major surface 90b.

Moreover, at least one of the inductors 65, 66, 67, 75, and 76, the capacitors 64, 80, 86, and 87, and the resistance element 89 may be provided outside of the semiconductor IC 82 and may be an SMD disposed on the major surface 90a.

The switches 48 and 49 may be formed on the major surface 90b instead of in the semiconductor IC 82. Furthermore, the switches 48 and 49 may be included, together with the control circuit, in a semiconductor IC disposed on the major surface 90b. In this case, the semiconductor IC including the switches 48 and 49 and the control circuit may at least partially overlap the amplifiers 11 and 12 in plan view of the major surfaces 90a and 90b. This configuration makes it possible to shorten wires connecting the amplifiers 11 and 12 to the switches 48 and 49 and thereby makes it possible to reduce the signal transmission loss on the input side of the amplifiers 11 and 12.

The inductors 60, 61, 62, 68, and 69, the capacitors 63, 83, 84, and 85, the switches 40 and 47, and the resistance element 88 are, for example, SMDs.

The switches 40 and 47 may be disposed on the major surface 90b. Furthermore, the switches 40 and 47 may be included, together with the control circuit, in a semiconductor IC disposed on the major surface 90b. In this case, the semiconductor IC including the switches 40 and 47 and the control circuit may at least partially overlaps the amplifiers 11 and 12 in plan view of the major surfaces 90a and 90b. This configuration makes it possible to shorten wires connecting the amplifiers 11 and 12 to the switches 40 and 47 and thereby makes it possible to reduce the signal transmission loss on the output side of the amplifiers 11 and 12.

Also, at least one of the inductors 60, 61, 62, 68, and 69, the capacitors 63, 83, 84, and 85, and the resistance element 88 may be implemented by conductor wires formed on or in the module substrate 90.

### 2.3 Effects

The amplifier circuit 10A according to the present embodiment includes the amplifiers 11 and 12, the combiner circuit configured to combine an output of the amplifier 11 and an output of the amplifier 12, and the signal output terminal 102 connected to the combiner circuit. The combiner circuit includes the first phase shifter, the third phase shifter, the fourth phase shifter, and the fifth phase shifter, each of which delays the phase of an input radio frequency signal by 45°; the second phase shifter and the sixth phase shifter, each of which advances the phase of an input radio frequency signal by 45°; the resistance element 88; and the switches 40 and 47 that include the terminals 40a, 40b, 40c, 47a, 47b, and 47c and are configured to switch between a connection configuration in which the terminal 40a is connected to the terminal 40b and a connection configuration in which the terminal 40a is connected to the terminal 40c and to switch among a connection configuration in which the terminal 47a is connected to the terminal 40b, a connection configuration in which the terminal 47a is connected to the terminal 47b, and a connection configuration in which the terminal 47a is connected to the terminal 47c. The input end of the first phase shifter is connected to the output end of the amplifier 11, the output end of the first phase shifter is connected to the terminal 40a, the input end of the second phase shifter is connected to the output end of the amplifier 12, the output end of the second phase shifter is connected to the terminal 47a, the input end of the third phase shifter is connected to the terminal 40b, the output end of the third phase shifter is connected to the signal output terminal 102, the input end of the fourth phase shifter is connected to the terminal 40c, the output end of the fourth phase shifter is connected to the signal output terminal 102, the input end of the fifth phase shifter is connected to the terminal 47b, the output end of the fifth phase shifter is connected to the signal output terminal 102, the input end of the sixth phase shifter is connected to the terminal 47c, the output end of the sixth phase shifter is connected to the signal output terminal 102, the first end of the resistance element 88 is connected to the terminal 40c, and the second end of the resistance element 88 is connected to the terminal 47b.

With this configuration, by changing the connection configurations of the switches 40 and 47, the amplifier circuit 10A can selectively operate in (1) the differential amplification mode, (2) the balanced amplification mode, (3) the Doherty amplification mode, or (4) the Doherty half amplification mode. Thus, this configuration makes it possible to provide a compact amplifier circuit 10A that can operate in the differential amplification mode, the balanced amplification mode, the Doherty amplification mode, and the Doherty half amplification mode.

Also, for example, in the amplifier circuit 10A, the first phase shifter includes the inductor 68 connected between the output end of the amplifier 11 and the terminal 40a and the capacitor 85 connected between the ground and the path connecting the inductor 68 to the terminal 40a; and the second phase shifter includes the capacitor 84 connected between the output end of the amplifier 12 and the terminal 47a and the inductor 69 connected between the ground and the path connecting the capacitor 84 to the terminal 47a.

This configuration makes it possible to implement each of the first phase shifter and the second phase shifter with an inductor and a capacitor and thereby makes it possible to simplify the amplifier circuit 10A.

Also, for example, in the amplifier circuit 10A, the third phase shifter includes the inductor 60 connected between the terminal 40b and the signal output terminal 102; the fourth phase shifter includes the inductor 61 connected between the terminal 40c and the signal output terminal 102; the fifth phase shifter includes the inductor 62 connected between the terminal 47b and the signal output terminal 102; and the sixth phase shifter includes the capacitor 63 connected between the terminal 47c and the signal output terminal 102.

This configuration makes it possible to implement each of the third through sixth phase shifters with an inductor or a capacitor and thereby makes it possible to simplify the amplifier circuit 10A.

Also, for example, in the differential amplification mode of the amplifier circuit 10A, the terminal 40a is connected to the terminal 40b, and the terminal 47a is connected to the terminal 47c. In the balanced amplification mode, the terminal 40a is connected to the terminal 40c, and the terminal 47a is connected to the terminal 47b. In the Doherty amplification mode, the terminal 40a is connected to the terminal 40b, and the terminal 47a is connected to the terminal 47b. Also, in the Doherty half amplification mode, the terminal 40a is connected to the terminal 40b, and the terminal 47a is connected to the terminal 40b.

This configuration makes it possible to implement four amplification modes by changing the connection configurations of the switches 40 and 47 and thereby makes it possible to simplify the amplifier circuit 10A.

Also, for example, when the amplifier circuit 10A is operated in the ET mode, the differential amplification mode or the balanced amplification mode is selected; and when the amplifier circuit 10A is operated in the APT mode, the Doherty amplification mode or the Doherty half amplification mode is selected.

This configuration makes it possible to improve load variation tolerance or peak efficiency in the ET mode and to improve backoff efficiency in the APT mode.

When the first radio frequency signal in the band A and the second radio frequency signal in the band B are simultaneously amplified by the amplifier circuit 10A, the balanced amplification mode, the Doherty amplification mode, or the Doherty half amplification mode is selected. When only one of the first radio frequency signal and the second radio frequency signal is amplified by the amplifier circuit 10A, the differential amplification mode is selected.

When a radio frequency signal in the band A and a radio frequency signal in the band B are transmitted simultaneously, this configuration makes it possible to improve load variation tolerance or backoff efficiency.

Also, for example, when the amplifier circuit 10A is operated in the low power mode, the Doherty amplification mode or the Doherty half amplification mode is selected; and when the amplifier circuit 10A is operated in the high power mode, the differential amplification mode or the balanced amplification mode is selected.

This makes it possible to improve load variation tolerance or peak efficiency in the high power mode and makes it possible to improve backoff efficiency in the low power mode.

Also, for example, the amplifier circuit 10A further includes the signal input terminal 101 and the splitter circuit configured to split a radio frequency signal input from the signal input terminal 101 into two radio frequency signals and output the two radio frequency signals to the amplifiers 11 and 12, respectively. The splitter circuit includes the seventh phase shifter and the ninth phase shifter, each of which advances the phase of an input radio frequency signal by 45°; the eighth phase shifter, the tenth phase shifter, the eleventh phase shifter, and the twelfth phase shifter, each of which delays the phase of an input radio frequency signal by 45°; the resistance element 89; and the switches 48 and 49 that include the terminals 48a, 48b, 48c, 49a, 49b, and 49c and are configured to switch among a connection configuration in which the terminal 48a is connected to the terminal 49c, a connection configuration in which the terminal 48a is connected to the terminal 48b, and a connection configuration in which the terminal 48a is connected to the terminal 48c and to switch between a connection configuration in which the terminal 49a is connected to the terminal 49b and a connection configuration in which the terminal 49a is connected to the terminal 49c. The input end of the seventh phase shifter is connected to the terminal 48a, the output end of the seventh phase shifter is connected to the input of the amplifier 11, the input end of the eighth phase shifter is connected to the terminal 49a, the output end of the eighth phase shifter is connected to the input end of the amplifier 12, the input end of the ninth phase shifter is connected to the signal input terminal 101, the output end of the ninth phase shifter is connected to terminal 48b, the input end of the tenth phase shifter is connected to the signal input terminal 101, the output end of the tenth phase shifter is connected to the terminal 48c, the input end of the eleventh phase shifter is connected to the signal input terminal 101, the output end of the eleventh phase shifter is connected to the terminal 49b, the input end of the twelfth phase shifter is connected to the signal input terminal 101, the output end of the twelfth phase shifter is connected to the terminal 49c, the first end of the resistance element 89 is connected to the terminal 48c, and the second end of the resistance element 89 is connected to the terminal 49b.

With this configuration, the splitter circuit can change the phases of radio frequency signals input to the amplifiers 11 and 12 by changing the connection configurations of the switches 48 and 49.

### OTHER EMBODIMENTS

Amplifier circuits according to the embodiments of the present disclosure and their variations are described above. However, the present disclosure is not limited to the amplifier circuits according to the embodiments and the variations described above. The present disclosure may also include other embodiments implemented by combining components in the above embodiments and variations, other variations obtained by making various modifications conceivable by a person skilled in the art to the embodiments and variations without departing from the spirit of the present disclosure, and various devices including the amplifier circuits described above.

For example, in the amplifier circuits, the radio frequency circuits, and the communication apparatuses according to the above embodiments and variations, another component, such as a circuit element or a wire, may be inserted in a path connecting circuit elements and signal paths disclosed in the drawings.

Features of the amplifier circuits according to the above embodiments are described below.

<1>

An amplifier circuit includes a first amplifier; a second amplifier; a combiner circuit configured to combine an output of the first amplifier and an output of the second amplifier; and a signal output terminal connected to the combiner circuit. The combiner circuit includes a first transformer including a first input-side coil and a first output-side coil; a second transformer including a second input-side coil and a second output-side coil; a first resistance element; a first switch that includes a first terminal, a second terminal, a third terminal, and a fourth terminal and is configured to switch between a connection configuration in which the first terminal is connected to the third terminal and the second terminal is connected to the fourth terminal and a connection configuration in which the first terminal is connected to the fourth terminal and the second terminal is connected to the third terminal; and a second switch that includes a fifth terminal, a sixth terminal, and a seventh terminal and is configured to switch between a connection configuration in which the fifth terminal is connected to the sixth terminal and a connection configuration in which the fifth terminal is connected to the seventh terminal. A first end of the first input-side coil is connected to the output end of the first amplifier; a second end of the first input-side coil is connected to the first terminal; a first end of the second input-side coil is connected to the output end of the second amplifier; a second end of the second input-side coil is connected to the third terminal; a first end of the first output-side coil is connected to the signal output terminal; a second end of the first output-side coil is connected to the second terminal; a first end of the second output-side coil is connected to the fifth terminal; a second end of the second output-side coil is connected to the fourth terminal; a first end of the first resistance element is connected to the sixth terminal; and a second end of the first resistance element and the seventh terminal are connected to the ground.

<2>

The amplifier circuit described in <1> further includes a first inductor; a second inductor; and a power supply voltage terminal. A first end of the first inductor is connected to the output end of the first amplifier and the first end of the first input-side coil; a first end of the second inductor is connected to the output end of the second amplifier and the first end of the second input-side coil; and a second end of the first inductor and a second end of the second inductor are connected to the power supply voltage terminal.

<3>

The amplifier circuit described in <1> or <2> further includes a first capacitor and a second capacitor. A first end of the first capacitor is connected to the first end of the first input-side coil; a second end of the first capacitor is connected to the first end of the first output-side coil; a first end of the second capacitor is connected to the first end of the second input-side coil; and a second end of the second capacitor is connected to the first end of the second output-side coil.

<4>

In the amplifier circuit described in any one of <1> to <3>, in a differential amplification mode in which the phase difference between a signal output from the first amplifier and a signal output from the second amplifier is 180°, the first terminal is connected to the third terminal, the second terminal is connected to the fourth terminal, and the fifth terminal is connected to the seventh terminal. In a balanced amplification mode in which the phase difference between a signal output from the first amplifier and a signal output from the second amplifier is 90°, the first terminal is connected to the fourth terminal, the second terminal is connected to the third terminal, and the fifth terminal is connected to the sixth terminal. In a Doherty amplification mode in which the first amplifier is a carrier amplifier, the second amplifier is a peak amplifier, and the phase difference between a signal output from the first amplifier and a signal output from the second amplifier is 90°, the first terminal is connected to the fourth terminal, the second terminal is connected to the third terminal, and the fifth terminal is connected to the seventh terminal.

<5>

In the amplifier circuit described in <4>, when the amplifier circuit is operated in an ET mode in which a power supply voltage supplied to the first amplifier and the second amplifier is varied according to envelope signals of radio frequency signals input to the first amplifier and the second amplifier, the differential amplification mode or the balanced amplification mode is selected. When the amplifier circuit is operated in an average power tracking mode in which the power supply voltage supplied to the first amplifier and the second amplifier is varied according to the average output power of radio frequency signals output from the first amplifier and the second amplifier, the Doherty amplification mode is selected.

<6>

In the amplifier circuit described in <4>, when a first radio frequency signal in a first band and a second radio frequency signal in a second band different from the first band are simultaneously amplified by the amplifier circuit, the balanced amplification mode or the Doherty amplification mode is selected; and when only one of the first radio frequency signal and the second radio frequency signal is amplified by the amplifier circuit, the differential amplification mode is selected.

<7>

In the amplifier circuit described in <4>, when the amplifier circuit is operated in a low power mode, the Doherty amplification mode is selected; and when the amplifier circuit is operated in a high power mode, the differential amplification mode or the balanced amplification mode is selected.

<8>

The amplifier circuit described in any one of <1> to <7> further includes a signal input terminal; and a splitter circuit configured to split a radio frequency signal input from the signal input terminal into two radio frequency signals and output the two radio frequency signals to the first amplifier and the second amplifier, respectively. The splitter circuit includes a third transformer including a third input-side coil and a third output-side coil; a fourth transformer including a fourth input-side coil and a fourth output-side coil; a second resistance element; a third switch that includes an eighth terminal, a ninth terminal, a tenth terminal, and an eleventh terminal and is configured to switch between a connection configuration in which the eighth terminal is connected to the tenth terminal and the ninth terminal is connected to the eleventh terminal and a connection configuration in which the eighth terminal is connected to the eleventh terminal and the ninth terminal is connected to the tenth terminal; and a fourth switch that includes a twelfth terminal, a thirteenth terminal, and a fourteenth terminal and is configured to switch between a connection configuration in which the twelfth terminal is connected to the thirteenth terminal and a connection configuration in which the twelfth terminal is connected to the fourteenth terminal. A first end of the third input-side coil is connected to the twelfth terminal; a second end of the third input-side coil is connected to the eighth terminal; a first end of the fourth input-side coil is connected to the signal input terminal; a second end of the fourth input-side coil is connected to the tenth terminal; a first end of the third output-side coil is connected to the input end of the first amplifier; a second end of the third output-side coil is connected to the ninth terminal; a first end of the fourth output-side coil is connected to the input end of the second amplifier; a second end of the fourth output-side coil is connected to the eleventh terminal; a first end of the second resistance element is connected to the thirteenth terminal; and a second end of the second resistance element and the fourteenth terminal are connected to the ground.

<9>

An amplifier circuit includes a first amplifier; a second amplifier; a combiner circuit configured to combine an output of the first amplifier and an output of the second amplifier; and a signal output terminal connected to the combiner circuit. The combiner circuit includes a first phase shifter that delays the phase of an input radio frequency signal by 45°; a second phase shifter that advances the phase of an input radio frequency signal by 45°; a third phase shifter that delays the phase of an input radio frequency signal by 45°; a fourth phase shifter that delays the phase of an input radio frequency signal by 45°; a fifth phase shifter that delays the phase of an input radio frequency signal by 45°; a sixth phase shifter that advances the phase of an input radio frequency signal by 45°; a first resistance element; and a first switch that includes a first terminal, a second terminal, a third terminal, a fourth terminal, a fifth terminal, and a sixth terminal and is configured to switch between a connection configuration in which the first terminal is connected to the second terminal and a connection configuration in which the first terminal is connected to the third terminal and to switch among a connection configuration in which the fourth terminal is connected to the second terminal, a connection configuration in which the fourth terminal is connected to the fifth terminal, and a connection configuration in which the fourth terminal is connected to the sixth terminal. The input end of the first phase shifter is connected to the output end of the first amplifier; the output end of the first phase shifter is connected to the first terminal; the input end of the second phase shifter is connected to the output end of the second amplifier; the output end of the second phase shifter is connected to the fourth terminal; the input end of the third phase shifter is connected to the second terminal; the output end of the third phase shifter is connected to the signal output terminal; the input end of the fourth phase shifter is connected to the third terminal; the output end of the fourth phase shifter is connected to the signal output terminal; the input end of the fifth phase shifter is connected to the fifth terminal; the output end of the fifth phase shifter is connected to the signal output terminal; the input end of the sixth phase shifter is connected to the sixth terminal; the output end of the sixth phase shifter is connected to the signal output terminal; a first end of the first resistance element is connected to the third terminal; and a second end of the first resistance element is connected to the fifth terminal.

<10>

In the amplifier circuit described in <9>, the first phase shifter includes a first inductor connected between the output end of the first amplifier and the first terminal and a first capacitor connected between the ground and a path connecting the first inductor to the first terminal; and the second phase shifter includes a second capacitor connected between the output end of the second amplifier and the fourth terminal, and a second inductor connected between the ground and a path connecting the second capacitor to the fourth terminal.

<11>

In the amplifier circuit described in <9> or <10>, the third phase shifter includes a third inductor connected between the second terminal and the signal output terminal; the fourth phase shifter includes a fourth inductor connected between the third terminal and the signal output terminal; the fifth phase shifter includes a fifth inductor connected between the fifth terminal and the signal output terminal; and the sixth phase shifter includes a third capacitor connected between the sixth terminal and the signal output terminal.

<12>

In the amplifier circuit described in any one of <9> to <11>, in a differential amplification mode in which the phase difference between a signal output from the first amplifier and a signal output from the second amplifier is 180°, the first terminal is connected to the second terminal, and the fourth terminal is connected to the sixth terminal; in a balanced amplification mode in which the phase difference between a signal output from the first amplifier and a signal output from the second amplifier is 90°, the first terminal is connected to the third terminal, and the fourth terminal is connected to the fifth terminal; in a Doherty amplification mode in which the first amplifier is a carrier amplifier, the second amplifier is a peak amplifier, and the phase difference between a signal output from the first amplifier and a signal output from the second amplifier is 90°, the first terminal is connected to the second terminal, and the fourth terminal is connected to the fifth terminal; and in a Doherty half amplification mode in which the first amplifier is a carrier amplifier, the second amplifier is a peak amplifier, and the phase difference between a signal output from the first amplifier and a signal output from the second amplifier is 90°, the first terminal is connected to the second terminal, and the fourth terminal is connected to the second terminal.

<13>

In the amplifier circuit described in <12>, when the amplifier circuit is operated in an ET mode in which a power supply voltage supplied to the first amplifier and the second amplifier is varied according to envelope signals of radio frequency signals input to the first amplifier and the second amplifier, the differential amplification mode or the balanced amplification mode is selected; and when the amplifier circuit is operated in an average power tracking mode in which the power supply voltage supplied to the first amplifier and the second amplifier is varied according to an average output power of radio frequency signals output from the first amplifier and the second amplifier, the Doherty amplification mode or the Doherty half amplification mode is selected.

<14>

In the amplifier circuit described in <12>, when a first radio frequency signal in a first band and a second radio frequency signal in a second band different from the first band are simultaneously amplified by the amplifier circuit, the balanced amplification mode, the Doherty amplification mode, or the Doherty half amplification mode is selected; and when only one of the first radio frequency signal and the second radio frequency signal is amplified by the amplifier circuit, the differential amplification mode is selected.

<15>

In the amplifier circuit described in <12>, when the amplifier circuit is operated in a low power mode, the Doherty amplification mode or the Doherty half amplification mode is selected; and when the amplifier circuit is operated in a high power mode, the differential amplification mode or the balanced amplification mode is selected.

<16>

The amplifier circuit described in any one of <9> to <15> further includes a signal input terminal; and a splitter circuit configured to split a radio frequency signal input from the signal input terminal into two radio frequency signals and output the two radio frequency signals to the first amplifier and the second amplifier, respectively. The splitter circuit includes a seventh phase shifter that advances the phase of an input radio frequency signal by 45°; an eighth phase shifter that delays the phase of an input radio frequency signal by 45°; a ninth phase shifter that advances the phase of an input radio frequency signal by 45°; a tenth phase shifter that delays the phase of an input radio frequency signal by 45°; an eleventh phase shifter that delays the phase of an input radio frequency signal by 45°; a twelfth phase shifter that delays the phase of an input radio frequency signal by 45°; a second resistance element; and a second switch that includes a seventh terminal, an eighth terminal, a ninth terminal, a tenth terminal, an eleventh terminal, and a twelfth terminal and is configured to switch among a connection configuration in which the seventh terminal is connected to the twelfth terminal, a connection configuration in which the seventh terminal is connected to the eighth terminal, and a connection configuration in which the seventh terminal is connected to the ninth terminal and to switch between a connection configuration in which the tenth terminal is connected to the eleventh terminal and a connection configuration in which the tenth terminal is connected to the twelfth terminal. The input end of the seventh phase shifter is connected to the seventh terminal; the output end of the seventh phase shifter is connected to the input end of the first amplifier; the input end of the eighth phase shifter is connected to the tenth terminal; the output end of the eighth phase shifter is connected to the input end of the second amplifier; the input end of the ninth phase shifter is connected to the signal input terminal; the output end of the ninth phase shifter is connected to the eighth terminal; the input end of the tenth phase shifter is connected to the signal input terminal; the output end of the tenth phase shifter is connected to the ninth terminal; the input end of the eleventh phase shifter is connected to the signal input terminal; the output end of the eleventh phase shifter is connected to the eleventh terminal; the input end of the twelfth phase shifter is connected to the signal input terminal; the output end of the twelfth phase shifter is connected to the twelfth terminal; a first end of the second resistance element is connected to the ninth terminal; and a second end of the second resistance element is connected to the eleventh terminal.

<17>

An amplifier circuit includes a first amplifier; a second amplifier; a combiner circuit configured to combine an output of the first amplifier and an output of the second amplifier; and a signal output terminal connected to the combiner circuit. The combiner circuit includes a first transformer including a first input-side coil and a first output-side coil; a second transformer including a second input-side coil and a second output-side coil; a first resistance element; and a first switch that includes a first terminal, a second terminal, a third terminal, and a fourth terminal and is configured to switch between a connection configuration in which the first terminal is connected to the third terminal and the second terminal is connected to the fourth terminal and a connection configuration in which the first terminal is connected to the fourth terminal and the second terminal is connected to the third terminal. A first end of the first input-side coil is connected to the output end of the first amplifier; a second end of the first input-side coil is connected to the first terminal; a first end of the second input-side coil is connected to the output end of the second amplifier; a second end of the second input-side coil is connected to the third terminal; a first end of the first output-side coil is connected to the signal output terminal; a second end of the first output-side coil is connected to the second terminal; a first end of the second output-side coil is connected to the ground; and a second end of the second output-side coil is connected to the fourth terminal.

<18>

In the amplifier circuit described in <17>, in a differential amplification mode in which a phase difference between a signal output from the first amplifier and a signal output from the second amplifier is 180°, the first terminal is connected to the third terminal, and the second terminal is connected to the fourth terminal; and in a Doherty amplification mode in which the first amplifier is a carrier amplifier, the second amplifier is a peak amplifier, and the phase difference between a signal output from the first amplifier and a signal output from the second amplifier is 90°, the first terminal is connected to the fourth terminal, and the second terminal is connected to the third terminal.

### INDUSTRIAL APPLICABILITY

The present disclosure can be widely used for communication devices, such as mobile phones, as an amplifier circuit provided in a front-end unit.

### REFERENCE SIGNS LIST

1, 1A radio frequency circuit
2 antenna
3 RF signal processing circuit (RFIC)
4, 4A communication apparatus
10, 10A amplifier circuit
11, 12 amplifier
13, 14 low-noise amplifier
21, 22, 23, 24 transformer
31, 32, 33, 34, 35, 36, 37, 38, 39, 63, 64, 80, 83, 84, 85, 86, 87 capacitor
40, 41, 42, 43, 44, 45, 46, 47, 48, 49 switch
40a, 40b, 40c, 41a, 41b, 41c, 41d, 42a, 42b, 42c, 42d, 43a, 43b, 43c, 44a, 44b, 44c, 47a, 47b, 47c, 48a, 48b, 48c, 49a, 49b, 49c terminal
51, 52, 53, 54, 55, 56, 57, 60, 61, 62, 65, 66, 67, 68,
69, 75, 76 inductor
71, 72, 73, 74 filter
78, 79, 88, 89 resistance element
81, 82 semiconductor IC
90 module substrate
90a, 90b major surface
91 resin component
92, 93, 94, 95 phase shift line
96 shield electrode layer
100 antenna connection terminal
101 signal input terminal
102 signal output terminal
211, 221, 231, 241 input-side coil
212, 222, 232, 242 output-side coil

1. An amplifier circuit comprising:
a first amplifier;
a second amplifier;
a combiner circuit configured to combine an output of the first amplifier and an output of the second amplifier; and
a signal output terminal connected to the combiner circuit, wherein
the combiner circuit includes
a first transformer including a first input-side coil and a first output-side coil,
a second transformer including a second input-side coil and a second output-side coil,
a first resistance element,
a first switch that includes a first terminal, a second terminal, a third terminal, and a fourth terminal and is configured to switch between a connection configuration in which the first terminal is connected to the third terminal and the second terminal is connected to the fourth terminal and a connection configuration in which the first terminal is connected to the fourth terminal and the second terminal is connected to the third terminal, and
a second switch that includes a fifth terminal, a sixth terminal, and a seventh terminal and is configured to switch between a connection configuration in which the fifth terminal is connected to the sixth terminal and a connection configuration in which the fifth terminal is connected to the seventh terminal;
a first end of the first input-side coil is connected to an output end of the first amplifier;
a second end of the first input-side coil is connected to the first terminal;
a first end of the second input-side coil is connected to an output end of the second amplifier;
a second end of the second input-side coil is connected to the third terminal;
a first end of the first output-side coil is connected to the signal output terminal;
a second end of the first output-side coil is connected to the second terminal;
a first end of the second output-side coil is connected to the fifth terminal;
a second end of the second output-side coil is connected to the fourth terminal;
a first end of the first resistance element is connected to the sixth terminal; and
a second end of the first resistance element and the seventh terminal are connected to a ground.

2. The amplifier circuit according to claim 1, further comprising:
a first inductor;
a second inductor; and
a power supply voltage terminal, wherein
a first end of the first inductor is connected to the output end of the first amplifier and the first end of the first input-side coil;
a first end of the second inductor is connected to the output end of the second amplifier and the first end of the second input-side coil; and
a second end of the first inductor and a second end of the second inductor are connected to the power supply voltage terminal.

3. The amplifier circuit according to claim 1, further comprising:
a first capacitor; and
a second capacitor, wherein
a first end of the first capacitor is connected to the first end of the first input-side coil;
a second end of the first capacitor is connected to the first end of the first output-side coil;
a first end of the second capacitor is connected to the first end of the second input-side coil; and
a second end of the second capacitor is connected to the first end of the second output-side coil.

4. The amplifier circuit according to claim 1, wherein
in a differential amplification mode in which a phase difference between a signal output from the first amplifier and a signal output from the second amplifier is 180°, the first terminal is connected to the third terminal, the second terminal is connected to the fourth terminal, and the fifth terminal is connected to the seventh terminal;
in a balanced amplification mode in which a phase difference between a signal output from the first amplifier and a signal output from the second amplifier is 90°, the first terminal is connected to the fourth terminal, the second terminal is connected to the third terminal, and the fifth terminal is connected to the sixth terminal; and
in a Doherty amplification mode in which the first amplifier is a carrier amplifier, the second amplifier is a peak amplifier, and a phase difference between a signal output from the first amplifier and a signal output from the second amplifier is 90°, the first terminal is connected to the fourth terminal, the second terminal is connected to the third terminal, and the fifth terminal is connected to the seventh terminal.

5. The amplifier circuit according to claim 4, wherein
when the amplifier circuit is operated in an envelope tracking (ET) mode in which a power supply voltage supplied to the first amplifier and the second amplifier is varied according to envelope signals of radio frequency signals input to the first amplifier and the second amplifier, the differential amplification mode or the balanced amplification mode is selected; and
when the amplifier circuit is operated in an average power tracking mode in which the power supply voltage supplied to the first amplifier and the second amplifier is varied according to an average output power of radio frequency signals output from the first amplifier and the second amplifier, the Doherty amplification mode is selected.

6. The amplifier circuit according to claim 4, wherein
when a first radio frequency signal in a first band and a second radio frequency signal in a second band different from the first band are simultaneously amplified by the amplifier circuit, the balanced amplification mode or the Doherty amplification mode is selected; and
when only one of the first radio frequency signal and the second radio frequency signal is amplified by the amplifier circuit, the differential amplification mode is selected.

7. The amplifier circuit according to claim 4, wherein
when the amplifier circuit is operated in a low power mode, the Doherty amplification mode is selected; and
when the amplifier circuit is operated in a high power mode, the differential amplification mode or the balanced amplification mode is selected.

8. The amplifier circuit according to claim 4, wherein the amplifier circuit is further configured to select one of the differential amplification mode, the balanced amplification mode, and the Doherty amplification mode by controlling a connection configuration of the first switch and a connection configuration of the second switch based on a predefined operating condition.

9. The amplifier circuit according to claim 1, further comprising:
a signal input terminal; and
a splitter circuit configured to split a radio frequency signal input from the signal input terminal into two radio frequency signals and output the two radio frequency signals to the first amplifier and the second amplifier, respectively, wherein
the splitter circuit includes
a third transformer including a third input-side coil and a third output-side coil,
a fourth transformer including a fourth input-side coil and a fourth output-side coil,
a second resistance element,
a third switch that includes an eighth terminal, a ninth terminal, a tenth terminal, and an eleventh terminal and is configured to switch between a connection configuration in which the eighth terminal is connected to the tenth terminal and the ninth terminal is connected to the eleventh terminal and a connection configuration in which the eighth terminal is connected to the eleventh terminal and the ninth terminal is connected to the tenth terminal, and
a fourth switch that includes a twelfth terminal, a thirteenth terminal, and a fourteenth terminal and is configured to switch between a connection configuration in which the twelfth terminal is connected to the thirteenth terminal and a connection configuration in which the twelfth terminal is connected to the fourteenth terminal;
a first end of the third input-side coil is connected to the twelfth terminal;
a second end of the third input-side coil is connected to the eighth terminal;
a first end of the fourth input-side coil is connected to the signal input terminal;
a second end of the fourth input-side coil is connected to the tenth terminal;
a first end of the third output-side coil is connected to an input end of the first amplifier;
a second end of the third output-side coil is connected to the ninth terminal;
a first end of the fourth output-side coil is connected to an input end of the second amplifier;
a second end of the fourth output-side coil is connected to the eleventh terminal;
a first end of the second resistance element is connected to the thirteenth terminal; and
a second end of the second resistance element and the fourteenth terminal are connected to the ground.

10. The amplifier circuit according to claim 1, further comprising a module substrate having a major surface, wherein the first amplifier and the second amplifier are included in a semiconductor integrated circuit disposed on the major surface of the module substrate, and wherein the first transformer and the second transformer are each formed by one or more conductive layers on or within the module substrate.

11. An amplifier circuit comprising:
a first amplifier having an input end and an output end;
a second amplifier having an input end and an output end;
a combiner circuit configured to combine an output of the first amplifier and an output of the second amplifier; and
a signal output terminal connected to the combiner circuit, wherein
the combiner circuit includes
a first phase shifter that delays a phase of an input radio frequency signal by 45°,
a second phase shifter that advances a phase of an input radio frequency signal by 45°,
a third phase shifter that delays a phase of an input radio frequency signal by 45°,
a fourth phase shifter that delays a phase of an input radio frequency signal by 45°,
a fifth phase shifter that delays a phase of an input radio frequency signal by 45°,
a sixth phase shifter that advances a phase of an input radio frequency signal by 45°,
a first resistance element, and
a first switch that includes a first terminal, a second terminal, a third terminal, a fourth terminal, a fifth terminal, and a sixth terminal and is configured to switch between a connection configuration in which the first terminal is connected to the second terminal and a connection configuration in which the first terminal is connected to the third terminal and to switch among a connection configuration in which the fourth terminal is connected to the second terminal, a connection configuration in which the fourth terminal is connected to the fifth terminal, and a connection configuration in which the fourth terminal is connected to the sixth terminal;
an input end of the first phase shifter is connected to the output end of the first amplifier;
an output end of the first phase shifter is connected to the first terminal;
an input end of the second phase shifter is connected to the output end of the second amplifier;
an output end of the second phase shifter is connected to the fourth terminal;
an input end of the third phase shifter is connected to the second terminal;
an output end of the third phase shifter is connected to the signal output terminal;
an input end of the fourth phase shifter is connected to the third terminal;
an output end of the fourth phase shifter is connected to the signal output terminal;
an input end of the fifth phase shifter is connected to the fifth terminal;
an output end of the fifth phase shifter is connected to the signal output terminal;
an input end of the sixth phase shifter is connected to the sixth terminal;
an output end of the sixth phase shifter is connected to the signal output terminal;
a first end of the first resistance element is connected to the third terminal; and
a second end of the first resistance element is connected to the fifth terminal.

12. The amplifier circuit according to claim 11, wherein
the first phase shifter includes
a first inductor connected between the output end of the first amplifier and the first terminal, and
a first capacitor connected between the ground and a path connecting the first inductor to the first terminal; and
the second phase shifter includes
a second capacitor connected between the output end of the second amplifier and the fourth terminal, and
a second inductor connected between the ground and a path connecting the second capacitor to the fourth terminal.

13. The amplifier circuit according to claim 11, wherein
the third phase shifter includes a third inductor connected between the second terminal and the signal output terminal;
the fourth phase shifter includes a fourth inductor connected between the third terminal and the signal output terminal;
the fifth phase shifter includes a fifth inductor connected between the fifth terminal and the signal output terminal; and
the sixth phase shifter includes a third capacitor connected between the sixth terminal and the signal output terminal.

14. The amplifier circuit according to claim 11, wherein
in a differential amplification mode in which a phase difference between a signal output from the first amplifier and a signal output from the second amplifier is 180°, the first terminal is connected to the second terminal, and the fourth terminal is connected to the sixth terminal;
in a balanced amplification mode in which a phase difference between a signal output from the first amplifier and a signal output from the second amplifier is 90°, the first terminal is connected to the third terminal, and the fourth terminal is connected to the fifth terminal;
in a Doherty amplification mode in which the first amplifier is a carrier amplifier, the second amplifier is a peak amplifier, and a phase difference between a signal output from the first amplifier and a signal output from the second amplifier is 90°, the first terminal is connected to the second terminal, and the fourth terminal is connected to the fifth terminal; and
in a Doherty half amplification mode in which the first amplifier is a carrier amplifier, the second amplifier is a peak amplifier, and a phase difference between a signal output from the first amplifier and a signal output from the second amplifier is 90°, the first terminal is connected to the second terminal, and the fourth terminal is connected to the second terminal.

15. The amplifier circuit according to claim 14, wherein
when the amplifier circuit is operated in an envelope tracking (ET) mode in which a power supply voltage supplied to the first amplifier and the second amplifier is varied according to envelope signals of radio frequency signals input to the first amplifier and the second amplifier, the differential amplification mode or the balanced amplification mode is selected; and
when the amplifier circuit is operated in an average power tracking mode in which the power supply voltage supplied to the first amplifier and the second amplifier is varied according to an average output power of radio frequency signals output from the first amplifier and the second amplifier, the Doherty amplification mode or the Doherty half amplification mode is selected.

16. The amplifier circuit according to claim 14, wherein
when a first radio frequency signal in a first band and a second radio frequency signal in a second band different from the first band are simultaneously amplified by the amplifier circuit, the balanced amplification mode, the Doherty amplification mode, or the Doherty half amplification mode is selected; and
when only one of the first radio frequency signal and the second radio frequency signal is amplified by the amplifier circuit, the differential amplification mode is selected.

17. The amplifier circuit according to claim 14, wherein
when the amplifier circuit is operated in a low power mode, the Doherty amplification mode or the Doherty half amplification mode is selected; and
when the amplifier circuit is operated in a high power mode, the differential amplification mode or the balanced amplification mode is selected.

18. The amplifier circuit according to claim 11, further comprising:
a signal input terminal; and
a splitter circuit configured to split a radio frequency signal input from the signal input terminal into two radio frequency signals and output the two radio frequency signals to the first amplifier and the second amplifier, respectively, wherein
the splitter circuit includes
a seventh phase shifter that advances a phase of an input radio frequency signal by 45°,
an eighth phase shifter that delays a phase of an input radio frequency signal by 45°,
a ninth phase shifter that advances a phase of an input radio frequency signal by 45°,
a tenth phase shifter that delays a phase of an input radio frequency signal by 45°,
an eleventh phase shifter that delays a phase of an input radio frequency signal by 45°,
a twelfth phase shifter that delays a phase of an input radio frequency signal by 45°,
a second resistance element, and
a second switch that includes a seventh terminal, an eighth terminal, a ninth terminal, a tenth terminal, an eleventh terminal, and a twelfth terminal and is configured to switch among a connection configuration in which the seventh terminal is connected to the twelfth terminal, a connection configuration in which the seventh terminal is connected to the eighth terminal, and a connection configuration in which the seventh terminal is connected to the ninth terminal and to switch between a connection configuration in which the tenth terminal is connected to the eleventh terminal and a connection configuration in which the tenth terminal is connected to the twelfth terminal;
an input end of the seventh phase shifter is connected to the seventh terminal;
an output end of the seventh phase shifter is connected to an input end of the first amplifier;
an input end of the eighth phase shifter is connected to the tenth terminal;
an output end of the eighth phase shifter is connected to an input end of the second amplifier;
an input end of the ninth phase shifter is connected to the signal input terminal;
an output end of the ninth phase shifter is connected to the eighth terminal;
an input end of the tenth phase shifter is connected to the signal input terminal;
an output end of the tenth phase shifter is connected to the ninth terminal;
an input end of the eleventh phase shifter is connected to the signal input terminal;
an output end of the eleventh phase shifter is connected to the eleventh terminal;
an input end of the twelfth phase shifter is connected to the signal input terminal;
an output end of the twelfth phase shifter is connected to the twelfth terminal;
a first end of the second resistance element is connected to the ninth terminal; and
a second end of the second resistance element is connected to the eleventh terminal.

19. An amplifier circuit comprising:
a first amplifier;
a second amplifier;
a combiner circuit configured to combine an output of the first amplifier and an output of the second amplifier; and
a signal output terminal connected to the combiner circuit, wherein
the combiner circuit includes
a first transformer including a first input-side coil and a first output-side coil,
a second transformer including a second input-side coil and a second output-side coil, and
a first switch that includes a first terminal, a second terminal, a third terminal, and a fourth terminal and is configured to switch between a connection configuration in which the first terminal is connected to the third terminal and the second terminal is connected to the fourth terminal and a connection configuration in which the first terminal is connected to the fourth terminal and the second terminal is connected to the third terminal, wherein a first end of the first input-side coil is connected to an output end of the first amplifier;
a second end of the first input-side coil is connected to the first terminal;
a first end of the second input-side coil is connected to an output end of the second amplifier;
a second end of the second input-side coil is connected to the third terminal;
a first end of the first output-side coil is connected to the signal output terminal;
a second end of the first output-side coil is connected to the second terminal;
a first end of the second output-side coil is connected to a ground; and
a second end of the second output-side coil is connected to the fourth terminal.

20. The amplifier circuit according to claim 19, wherein
in a differential amplification mode in which a phase difference between a signal output from the first amplifier and a signal output from the second amplifier is 180°, the first terminal is connected to the third terminal, and the second terminal is connected to the fourth terminal; and
in a Doherty amplification mode in which the first amplifier is a carrier amplifier, the second amplifier is a peak amplifier, and a phase difference between a signal output from the first amplifier and a signal output from the second amplifier is 90°, the first terminal is connected to the fourth terminal, and the second terminal is connected to the third terminal.
